(19) United States
(12) Patent Application Publication
(10) Pub. No.: US 2025/0359376 A1
(43) Pub. Date: Nov. 20, 2025

(54) IMAGE SENSOR

(71) Applicant: Samsung Electronics Co., Ltd., Suwon-si (KR)

(72) Inventors: Byungjun Park, Suwon-si (KR); Chanho Jo, Suwon-si (KR)

(21) Appl. No.: 19/003,282

(22) Filed: Dec. 27, 2024

(30) Foreign Application Priority Data
May 17, 2024 (KR) 10-2024-0064614

(51) Int. Cl. H10F 39/00

(52) U.S. Cl. CPC H10F 39/807; H10F 39/811; H10F 39/011

(57) ABSTRACT

The present disclosure relates to an image sensor, and more particularly, to an image sensor having an enhanced structure. An image sensor according to some embodiments includes a substrate, a plurality of unit regions, a plurality of isolation portions, and a doping region in the substrate. At least one of the plurality of unit regions include a photoelectric conversion portion in the substrate. The plurality of isolation portions are disposed to correspond to a boundary of the plurality of unit regions. The plurality of isolation portions include a first isolation portion and a second isolation portion that has a height less than a height of the first isolation portion. The plurality of isolation portions include a conductive layer. The doping region is electrically connected to a portion of the conductive layer in the second isolation portion.

### CROSS-REFERENCE TO RELATED APPLICATION

This application claims priority to and the benefit of Korean Patent Application No. 10-2024-0064614 filed in the Korean Intellectual Property Office on May 17, 2024,the entire contents of which are incorporated herein by reference.

### BACKGROUND

The present disclosure relates to an image sensor, and more particularly, to an image sensor having an enhanced structure.

An image sensor is a semiconductor device that converts optical images into electrical signals. The image sensors may be classified into charge coupled device (CCD) type image sensors based on silicon semiconductors and complementary metal oxide semiconductor (CMOS) type image sensors (CIS).

Among these, the CMOS type image sensor may be driven by a simple method and a signal processing circuit may be integrated on a single chip in the CMOS type image sensor. Therefore, the CMOS type image sensor may be downsized and have a low power consumption, and thus, may be applied to products with a limited battery capacity. With the advancement of the electronics industry, various studies are continuing to improve the performance of the CMOS type image sensors.

### SUMMARY

The present disclosure attempts to provide an image sensor capable of enhancing performance and productivity.

An image sensor according to some embodiments includes a substrate, a plurality of unit regions, a plurality of isolation portions, and a doping region in the substrate. At least one of the plurality of unit regions include a photoelectric conversion portion in the substrate. The plurality of isolation portions are disposed to correspond to a boundary of the plurality of unit regions. The plurality of isolation portions include a first isolation portion and a second isolation portion that has a height less than a height of the first isolation portion. The plurality of isolation portions include a conductive layer. The doping region is electrically connected to a portion of the conductive layer in the second isolation portion.

An image sensor according to some embodiments includes a substrate, a pixel array region comprising a plurality of pixel regions and a dummy array region comprising a plurality of dummy regions, a first isolation portion, a second isolation portion, and a doping region. The plurality of pixel regions includes a plurality of photoelectric conversion portions, respectively, in the substrate. The first isolation portion is in the pixel array region between ones of the plurality of photoelectric conversion portions of the plurality of pixel regions. The second isolation portion extends into the substrate to correspond to at least at a boundary of ones of the plurality of dummy regions. The second isolation portion includes a conductive end through which a conductive layer is exposed. The doping region is in the substrate and is electrically connected to the conductive end of the second isolation portion.

An image sensor according to some embodiments includes a photoelectric conversion substrate, and an additional wiring portion that is on a first surface of the photoelectric conversion substrate and includes a pad configured to be electrically connected to an outside element. The photoelectric conversion substrate includes a substrate, a plurality of unit regions, a plurality of isolation portions, a doping region, and a wiring portion. At least one of the plurality of unit regions include a photoelectric conversion portion in the substrate. The plurality of isolation portions are disposed to correspond to a boundary of the plurality of unit regions, and the plurality of isolation portions include a conductive layer. The doping region is in the substrate and is electrically connected to a portion of the conductive layer of the plurality of isolation portions. The wiring portion is adjacent to a first substrate surface of the substrate, and is electrically connected to the additional wiring portion. The wiring portion includes a connection wiring that is electrically connected to the doping region.

According to some embodiments, a doping region that is electrically connected to a conductive layer in at least one of a plurality of isolation portions (e.g., a second isolation portion) in a substrate may be used to enhance a dark current. For example, by applying a voltage (e.g., a negative voltage) to the isolation portion through a connection wiring that is electrically connected to the doping region, the dark current may be enhanced through a hole accumulation.

The connection wiring may be included in a wiring portion that is to be adjacent to a first substrate surface of the substrate and thus a path for applying the voltage to the isolation portion may be reduced and an image sensor may be manufactured by an easy process. Accordingly, performance of the image sensor may be enhanced by effectively applying the voltage to the isolation portion, and productivity and yield of the image sensor may be enhanced by simplifying a manufacturing process and reducing a process error.

### BRIEF DESCRIPTION OF THE DRAWINGS

FIG. 1 is a block diagram that schematically illustrates an example of an image sensor.

FIG. 2 is a plan view that schematically illustrates an image sensor according to some embodiments.

FIG. 3 is a schematic cross-sectional view taken along a line A-A′ in FIG. 2.

FIG. 4 is a rear plan view that illustrates a portion B of FIG. 2.

FIG. 5 is a cross-sectional view that illustrates a portion C of FIG. 3.

FIG. 6 is a rear plan view that illustrates a portion D of FIG. 2.

FIG. 7 to FIG. 16 are cross-sectional views that schematically illustrate a manufacturing method of an image sensor according to some embodiments.

FIG. 17 is a plan view that schematically illustrates an image sensor according to some embodiments.

FIG. 18 is a cross-sectional view that schematically illustrates an image sensor according to some embodiments.

FIG. 19 is a cross-sectional view that schematically illustrates an image sensor according to some embodiments.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiments provided herein.

A portion unrelated to the description is omitted in order to clearly describe the present disclosure, and the same or similar components are denoted by the same reference numeral throughout the present specification.

Further, since sizes and thicknesses of portions, regions, members, units, layers, films, or so on, illustrated in the accompanying drawings may be arbitrarily illustrated for better understanding and convenience of explanation, the present disclosure is not limited to the illustrated sizes and thicknesses. In the drawings, thicknesses of portions, regions, members, units, layers, films, or so on, may be enlarged or exaggerated for convenience of explanation and/or simple illustration.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a vertical cross-sectional viewed from a side. Two elements may be “connected” by being electrically connected and/or physically connected.

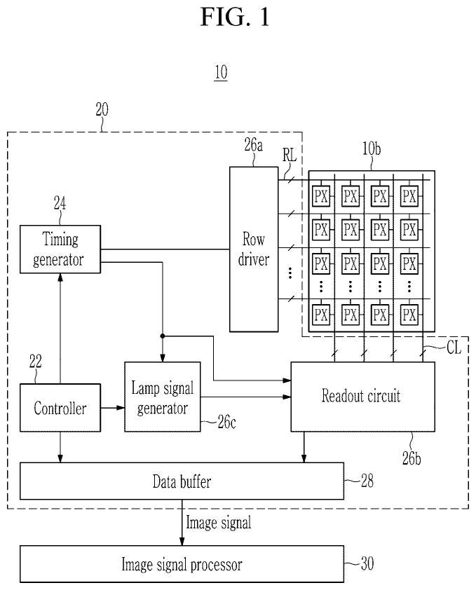

Hereinafter, an image sensor and a manufacturing method of the same according to some embodiments will be described in detail with reference to FIG. 1 to FIG. 16.

FIG. 1 is a block diagram that schematically illustrates an example of an image sensor 10.

Referring to FIG. 1, an image sensor 10 according to some embodiments may include a pixel array 10b, and a logic circuit 20 that controls the pixel array 10b. The logic circuit 20 is a circuit configured to control the pixel array 10b and may include, for example, a controller 22, a timing generator 24, a row driver 26a, a readout circuit 26b, a lamp signal generator 26c, and a data buffer 28. The image sensor 10 may further include an image signal processor 30. In some embodiments, the image signal processor 30 may be disposed outside the image sensor 10.

The image sensor 10 may generate an image signal by converting light received from the outside into an electric signal, and the image signal generated by the image sensor 10 may be provided to the image signal processor 30.

The image sensor 10 may be mounted on an electronic device with an image or light sensing function. For example, the image sensor 10 may be mounted on electronic devices such as cameras, smartphones, wearable devices, internet of things (IoT) devices, home appliance devices, tablets, personal digital assistants (PDA), portable multimedia players (PMP), navigations, drones, or advanced driver assistance systems (ADAS). In some embodiments, the image sensor 10 may be mounted on a vehicle, furniture, a manufacturing facility, a door, or an electronic device provided as a part of various measuring devices.

The pixel array 10b may include a plurality of pixel regions PX, and a plurality of row lines RL and a plurality of column lines CL respectively electrically connected to the plurality of pixel regions PX.

In some embodiments, each pixel region PX may include at least one photoelectric conversion device. The photoelectric conversion device may detect incident light and convert the incident light into the electric signal, that is, a plurality of analog pixel signals, according to an amount of light. The photoelectric conversion device may be a photodiode or a pinned diode. In some embodiments, the photoelectric conversion device may be a single-photon avalanche diode (SPAD) applied to a 3D sensor pixel. The level of the analog pixel signal output from the photoelectric conversion device may be proportional to the amount of light provided to each pixel region PX or the amount of charges output from the photoelectric conversion device.

The plurality of row lines RL may extend in one direction and be electrically connected to the plurality of pixel regions PX arranged in the one direction. For example, a control signal output from the row driver 26a to the row line RL may be transmitted to a gate of a transistor of the plurality of pixel regions PX connected to the row line RL. The column line CL may extend in a crossing direction that is transverse to, crosses, or intersects the one direction and may be connected to the plurality of pixel regions PX arranged in the crossing direction or intersecting direction that is transverse to the one direction. The plurality of pixel signals output from the plurality of pixel regions PX may be transmitted to the readout circuit 26b through the plurality of column lines CL.

In some embodiments, the plurality of pixel regions PX may be grouped in a form of a plurality of columns and a plurality of rows to form one unit pixel group. That is, a plurality of pixel regions PX arranged in an extension direction of the row line RL and a plurality of pixel regions PX arranged in an extension direction of the column line CL may form one unit pixel group. For example, one unit pixel group includes a plurality of pixels arranged in the form of two columns and two rows, and one unit pixel group may output one analog pixel signal. However, the embodiments are not limited thereto and various modifications are possible.

In some embodiments, each pixel region PX may include a pixel circuit that processes the charge generated by the photoelectric conversion device and outputs the electric signal. The pixel circuit may include a transfer transistor, a reset transistor, a selection transistor, a driving transistor, or so on. The embodiments are not limited thereto and the pixel circuit may have various structures.

The controller 22 may generally control the timing generator 24, the row driver 26a, the readout circuit 26b, the lamp signal generator 26c, and the data buffer 28 included in the image sensor 10. For example, the controller 22 may control an operation timing by using a control signal. In some embodiments, the controller 22 may receive a mode signal indicating an imaging mode from an application processor and generally control the image sensor 10 based on the received mode signal.

The timing generator 24 may generate a signal that serves as a reference for the operation timing of the image sensor 10. The timing generator 24 may provide a control signal that controls the timing of the row driver 26a, the readout circuit 26b, and the lamp signal generator 26c.

The row driver 26a may generate a control signal to drive the pixel array 10b in response to the control signal of the timing generator 24, and may provide the control signal to the plurality of pixel regions PX of the pixel array 10b through the plurality of row lines RL. For example, the row driver 26a may generate a transfer signal that controls the transfer transistor, a reset control signal that controls the reset transistor, and a selection control signal that controls the selection transistor, and provide the transfer signal, the reset control signal, and the selection signal to the pixel array 10b.

The readout circuit 26b may convert a pixel signal (or an electric signal) output through the corresponding column line CL into a pixel value representing the amount of light. The lamp signal generator 26c may generate a reference signal or a lamp signal and transmit the reference signal or the lamp signal to the readout circuit 26b. For example, the readout circuit 26b may convert the pixel signal to the pixel value by comparing the lamp signal and the pixel signal. The pixel value may be an image data with a plurality of bits.

The data buffer 28 may store the pixel value of the pixel region PX transmitted from the readout circuit 26b and may output the stored pixel value in response to a signal from the controller 22.

The image signal processor 30 may perform an image signal processing on the image signal received from the data buffer 28. For example, the image signal processor 30 may receive a plurality of image signals from the data buffer 28 and generate one image by combining the received image signals.

The embodiments are not limited to the above descriptions, and a structure, a type, or so on of the image sensor 10 may be variously modified.

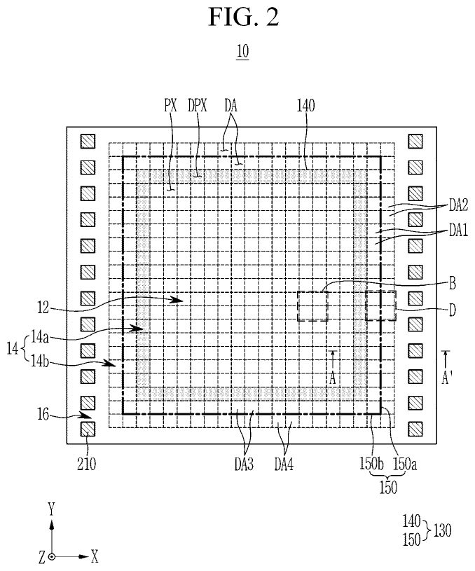

FIG. 2 is a plan view that schematically illustrates an image sensor 10 according to some embodiments. For a clear understanding, in FIG. 2, a pixel array region 12, a dummy array region 14, a pad region 16, a pixel region PX, a dummy pixel region DPX, a dummy region DA, an isolation portion 130, and a pad 210 of an image sensor 10 are mainly illustrated.

Referring to FIG. 2, an image sensor 10 according to some embodiments may include a pixel array region 12 and a dummy array region 14. In the pixel array region 12 and the dummy array region 14, a plurality of unit regions may be disposed. The unit regions may include a pixel region PX, a dummy pixel region DPX, and/or a dummy region DA.

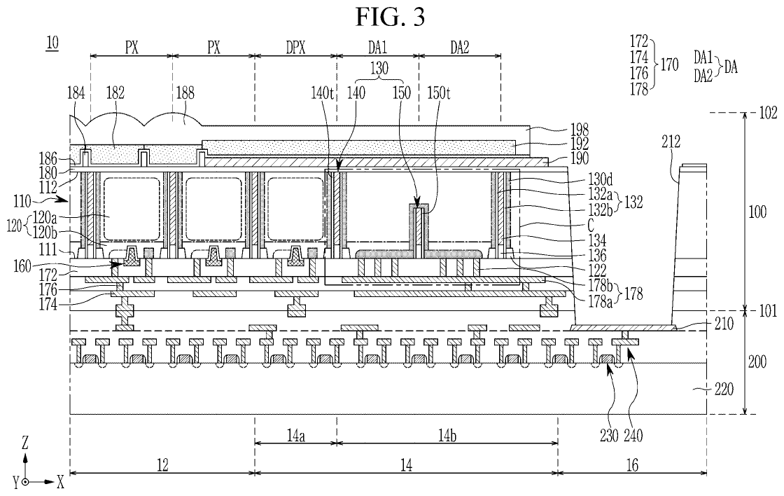

In a plan view, the pixel array regions 12 may be disposed in a central region of the image sensor 10, and the dummy array region 14 may be disposed in an outer region of the pixel array region 12 to surround the pixel array region 12. At least a partial portion of the dummy array region 14 may be an optical black region in which light is blocked by an optical black layer 190 (refer to FIG. 3).

In the pixel array region 12, a plurality of pixel regions PX may be disposed. The plurality of pixel regions PX may be disposed to have a plurality of rows and a plurality of columns. For example, the plurality of pixel regions PX may be adjacent to each other in each of a first direction (a Y-axis direction in the drawings) and in a second direction (an X-axis direction in the drawings) that is transverse to, intersects, or crosses the first direction. The pixel region PX may include a photoelectric conversion portion 120 (refer to FIG. 3) and a pixel circuit 160 (refer to FIG. 3).

In the dummy array region 14, at least a plurality of dummy regions DA may be disposed, and a plurality of dummy pixel regions DPX may be further disposed. The dummy pixel region DPX may include the photoelectric conversion portion 120 and/or the pixel circuit 160 that is included in the pixel region PX, and may provide a reference charge amount in a state that light is blocked. The dummy region DA might not include the photoelectric conversion portion 120 and the pixel circuit 160 and may have a structure different from structures of the pixel region PX and the dummy pixel region DPX. A first dummy array region 14a that includes the dummy pixel region DPX may be the optical black region in which the optical black layer 190 is disposed. A second dummy array region 14b that includes the dummy region DA may be the optical black region in which the optical black layer 190 is disposed or a region in which the optical black layer 190 is not disposed.

In FIG. 2, it is illustrated as an example that the first dummy array region 14a including the dummy pixel region DPX includes one column or row to surround the pixel array region 12 in the outer region of the pixel array region 12, and the second dummy array region 14b including the dummy region DA includes two columns or rows to surround the first dummy array region 14a in the outer region of the first dummy array region 14a. However, the embodiments are not limited thereto. Accordingly, an arrangement, a shape, or so on of the first dummy array region 14a and the second dummy array region 14b may be variously modified, and/or an arrangement, a number, or so on of the dummy pixel region DPX and the dummy region DA may be variously modified.

In some embodiments, the isolation portion 130 may include a first isolation portion 140 and a second isolation portion 150.

In a pad region 16, a pad 210 configured to be connected to an outside element may be disposed. The pad 210 may receive a voltage or voltage signal that is provided from an external circuit, or so on, and transmit the received voltage or voltage signal to the image sensor 10 to operate the image sensor 10 and may transmit an electrical signal generated in the pixel region PX and/or the dummy pixel region DPX to the external circuit or so on. In a plan view, the pad region 16 may be disposed in an edge portion of the image sensor 10. Thereby, the pad 210 may be easily connected to the external circuit or so on.

In FIG. 2, it is illustrated as an example that the pad regions 16 or the pads 210 may be disposed at both sides in the second direction (the X-axis direction in the drawings). However, the embodiments are not limited thereto. Accordingly, the pad region 16 or the pad 210 may be disposed at least one of both sides in the first direction (the Y-axis direction in the drawings), and/or may be disposed at least one of both sides in the second direction. A position, an arrangement, or so on of the pad region 16 or the pad 210 may be variously modified.

In FIG. 2, it is illustrated as an example that the isolation portion 130 is not disposed in the pad region 16. However, the embodiments are not limited thereto. In some embodiments, in the pad region 16, the isolation portion 130 or a structure that has a shape the same as or similar to a shape of the isolation portion 130 may be disposed for an electrical isolation.

Referring to FIG. 3 to FIG. 6 together with FIG. 2, the pixel region PX, the dummy pixel region DPX, the dummy region DA, the isolation portion 130, and the pad 210 will be described in more detail.

FIG. 3 is a schematic cross-sectional view taken along a line A-A′ in FIG. 2.

Referring to FIG. 2 and FIG. 3, the image sensor 10 according to some embodiments may include a photoelectric conversion substrate 100, and may further include an additional wiring portion 200 that is disposed on a first surface 101 of the photoelectric conversion substrate 100 and includes the pad 210 configured to be connected to the outside. A wiring portion 170 may be disposed to be adjacent to the first surface 101 (a lower surface in FIG. 3) of the photoelectric conversion substrate 100, and a light receiving portion that includes a color filter 182, a micro lens 188, or so on may be disposed to be adjacent to a second surface 102 (an upper surface in FIG. 3) of the photoelectric conversion substrate 100 that is opposite to the first surface 101. The photoelectric conversion substrate 100 may be referred as a photoelectric conversion structure.

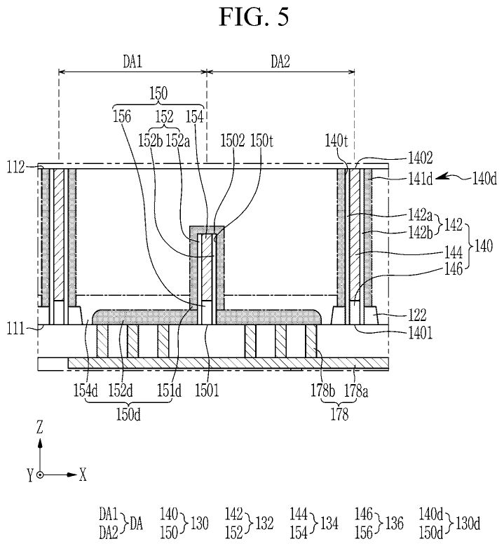

In some embodiments, the photoelectric conversion substrate 100 may include a substrate 110, a plurality of unit regions, a plurality of isolation portions 130, and a doping region 130d. At least one of unit regions may include a photoelectric conversion portion 120 in the substrate 110. The plurality of isolation portions 130 may separate, divide, or define partial portions (e.g., the plurality of photoelectric conversion portions 120) of the plurality of unit regions in the substrate 110 or may be disposed to correspond to a boundary of the plurality of unit regions. The isolation portions 130 may include a conductive layer 134. A doping region 130d may be disposed in the substrate 110. The doping region 130d may be electrically connected to a portion of the conductive layer 134 that is included in at least one of the plurality of isolation portions 130. For example, a second doping region 150d (refer to FIG. 5) may be electrically connected to a second conductive portion 154 (refer to FIG. 5) that is included in the second isolation portion 150. The plurality of unit regions may include the pixel region PX, the dummy pixel region DPX, and/or the dummy region DA. The isolation portion 130 may be disposed to separate, divide, or define partial portions (e.g., the plurality of photoelectric conversion portions 120) of the pixel region PX, the dummy pixel region DPX, and/or the dummy region DA in the substrate 110. The isolation portion 130 may be disposed to correspond to a boundary of the pixel region PX, the dummy pixel region DPX, and/or the dummy region DA in the substrate 110.

The pixel circuit 160 and the wiring portion 170 may be disposed to be adjacent to a first substrate surface 111 (a lower surface of FIG. 3) of the substrate 110, and the light receiving portion that includes the color filter 182, the micro lens 188, or so on may be disposed on a second substrate surface 112 (an upper surface in FIG. 3) of the substrate 110 that is opposite to the first substrate surface 111. The first substrate surface 111 of the substrate 110 may be an upper surface in a manufacturing process of the photoelectric conversion substrate 100, and the second substrate surface 112 of the substrate 110 may be a lower surface in the manufacturing process of the photoelectric conversion substrate 100.

In some embodiments, the substrate 110 may include or be formed of a semiconductor substrate including a semiconductor material. For example, the substrate 110 may include a bulk substrate including a semiconductor material, a substrate including a bulk substrate and an epitaxial layer on the bulk substrate, or a semiconductor-on-insulator. In this instance, the semiconductor material included in the substrate 110 may include a first conductivity type dopant to have a first conductivity type (e.g., a p-type or an n-type).

The semiconductor material included in the substrate 110 may include at least one of a group IV semiconductor, a group III-V compound semiconductor, or a group II-VI compound semiconductor. For example, the semiconductor material that is included in the substrate 110 may include at least one of Si, Ge, SiGe, SiC, GaAs, InAs, GaP, InP, InSb, InGaAs, ZnTe, or CdS. For example, the bulk substrate may be a single-crystalline or polycrystalline semiconductor substrate and may include Si, Ge, or SiGe. In some embodiments, the semiconductor-on-insulator may be a silicon-on-insulator (SOI), a germanium-on-insulator (GOI), or a silicon-germanium-on-insulator (SGOI).

In some embodiments, the substrate 110 may include the pixel array region 12 in which the plurality of pixel regions PX are disposed and the dummy array region 14 in which the plurality of dummy regions DA and/or the plurality of dummy pixel regions DPX are disposed.

In the pixel region PX and at least a partial portion of the dummy pixel region DPX of the substrate 110, the photoelectric conversion portion 120 configured to convert light to an electrical signal may be disposed. In the dummy region DA of the substrate 110, the photoelectric conversion portion 120 might not be disposed.

The photoelectric conversion portion 120 may include a second conductivity type well 120a and may further include a first conductivity type well 120b. The second conductivity type well 120a may include a second conductivity type dopant to have a second conductivity type (e.g., an n-type or a p-type) that is opposite to the substrate 110. The first conductivity type well 120b may include a first conductivity type dopant to have a first conductivity type (e.g., a p-type or an n-type). A photodiode may include a pn junction of the second conductivity type well 120a and the first conductivity type well 120b. The photoelectric conversion portion 120, which is part of the photodiode, may generate and accumulate charges in proportion to an amount of light provided to each pixel region PX or each dummy pixel region DPX. The second conductivity type well 120a may be formed by doping the second conductivity type dopant to the substrate 110, and the first conductivity type well 120b may be formed by doping the first conductivity type dopant to the substrate 110. In some embodiments, the first conductivity type well 120b may be omitted. In this instance, a photodiode may include a pn junction between the second conductivity type well 120a and the substrate 110 having the first conductivity type.

By the isolation portion 130, the photoelectric conversion portions 120 may correspond to at least the plurality of pixel regions PX, respectively. By the isolation portion 130, the photoelectric conversion portions 120 may correspond to at least a part of the plurality of dummy pixel regions DPX.

In an embodiment, a device isolation portion 122 may be disposed in a shallow trench (ST) to separate, divide, or define an active region in the pixel region PX or at least a part of the dummy pixel regions DPX. For example, the device isolation portion 122 may be a shallow trench isolation (STI). The device isolation portion 122 may include at least one of silicon oxide, silicon nitride, or silicon oxynitride, and the device isolation portion 122 may include a single layer or a plurality of layers. However, the embodiments are not limited thereto. Therefore, a material of the device isolation portion 122 may be variously modified, or the device isolation portion 122 may be omitted. In the drawings, a boundary of the device isolation portion 122 and the isolation portion 130 is illustrated for a clear understanding. However, in some embodiments, the boundary the device isolation portion 122 and the isolation portion 130 may be not confirmed and the device isolation portion 122 and the isolation portion may form an integral structure at a portion adjacent to first substrate surface 111 of the substrate 110.

The isolation portion 130 may pass through, penetrate, or extend into at least a partial portion of the substrate 110. The isolation portion 130 may be disposed in a first trench 140t or a second trench 150t that has a depth greater than the device isolation portion 122. For example, the first trench 140t or the second trench 150t may be a deep trench (DT). In some embodiments, the isolation portion 130 (e.g., the first isolation portion 140) may include a front deep trench isolation (FDTI) that includes a portion adjacent to the first substrate surface 111 of the substrate 110 and/or a back deep trench isolation (BDTI) that includes a portion adjacent to the second substrate surface 112 of the substrate 110. In FIG. 3, it is illustrated as an example that the isolation portion 130 (e.g., the first isolation portion 140) includes the front deep trench isolation, but the embodiments are not limited thereto. In the specification, a depth may correspond to a height in a thickness direction of the image sensor 10 (a Z-axis direction in the drawings) or a vertical direction.

In a plan view, the isolation portion 130 may include a first portion that extends in the first direction (the Y-axis direction in the drawings) and a second portion that extends in the second direction (the X-axis direction in the drawings). For example, in a plan view, the isolation portion 130 may have a lattice shape to correspond to the boundary of the plurality of pixel regions PX, the dummy pixel region DPX and/or the dummy region DA. Thereby, in a plan view, a pair of first portions and a pair of second portions may be disposed to correspond to a boundary of each pixel region PX, a pair of first portions and a pair of second portions may be disposed to correspond to a boundary of the dummy pixel region DPX, and a pair of first portions and a pair of second isolation portions may be disposed to correspond to a boundary of the dummy region DA.

In some embodiments, the isolation portion 130 may include the conductive layer 134. A dark current may be improved by the conductive layer 134 of the isolation portion 130. More particularly, the isolation portion 130 may include a sidewall insulation layer 132 and the conductive layer 134 disposed on the sidewall insulation layer 132, and may further include a capping portion 136.

The sidewall insulation layer 132 may include a first insulation portion 132a and a second insulation portion 132b, which are provided on both sides of the isolation portion 130, respectively, to be adjacent to two unit regions while interposing the isolation portion 130 therebetween.

The sidewall insulation layer 132 may include any of various insulating materials. For example, the sidewall insulation layer 132 may include oxide, nitride, oxynitride, or so on. More particularly, the sidewall insulation layer 132 may include an insulating material that includes silicon (e.g., silicon oxide, silicon nitride, silicon oxynitride, or so on). However, the embodiments are not limited to a material of the sidewall insulation layer 132. The sidewall insulation layer 132 may include a single layer or a plurality of layers.

The conductive layer 134 may be disposed between the first insulation portion 132a and the second insulation portion 132b. The conductive layer 134 may include any of various conductive materials. For example, the conductive layer 134 may include an undoped semiconductor material (e.g., an undoped polycrystalline semiconductor material, as an example, undoped polycrystalline silicon), a doped semiconductor material that includes a dopant (e.g., a doped polycrystalline semiconductor, as an example, doped polycrystalline silicon), or so on. The dopant included in the conductive layer 134 may be a p-type dopant or an n-type dopant, for example, the p-type dopant. For example, the p-type dopant may include boron, aluminum, gallium, indium, or so on.

In some embodiments, the conductive layer 134 may include a doped semiconductor layer and an undoped semiconductor layer. For example, the doped semiconductor layer may include a p-type polycrystalline silicon, and the undoped semiconductor layer may include an i-type polycrystalline silicon. However, the embodiments are not limited thereto. In some embodiments, a dopant (e.g., a p-type dopant) included in the doped semiconductor layer may be diffused to the undoped semiconductor layer and at least a partial portion of the undoped semiconductor layer may be changed to a doped semiconductor layer. In some embodiments, the conductive layer 134 may include any of various materials, and/or the conductive layer 134 may include a single layer or three or more layers.

The capping portion 136 may be disposed between the first insulation portion 132a and the second insulation portion 132b on the conductive layer 134 to be adjacent to the first substrate surface 111. For example, the capping portion 136 may include oxide, nitride, oxynitride, fluoride, or so on. More particularly, the capping portion 136 may include at least one of silicon oxide, silicon nitride, silicon oxynitride, aluminum oxide, or hafnium oxide. However, the embodiments are not limited to a material of the capping portion 136. The capping portion 136 may include a single layer or a plurality of layers.

The doping region 130d may be disposed at a portion of the substrate 110 that is adjacent to the isolation portion 130. The doping regions 130d may be disposed at least on both sidewalls of the isolation portion 130, respectively. The doping region 130d may improve a dark current, together with the conductive layer 134 of the isolation portion 130. In some embodiments, the doping region 130d may be electrically connected to a portion of the conductive layer 134 that is included in at least one of the plurality of isolation portions 130. For example, the doping region 130d may be electrically connected to a second conductive portion 154 that is included in the second isolation portion 150. The doping region 130d may have the first conductivity type (the p-type or the n-type) that is the same as a conductivity type of the substrate 110. For example, the doping region 130d may have the p-type. For example, the doping region 130d may include boron, aluminum, gallium, indium, or so on as a p-type dopant.

In FIG. 3, it is illustrated as an example that a surface of the device isolation portion 122 and a surface of the isolation portion 130 adjacent to the first substrate surface 111 of the substrate 110 are disposed on the same plane as the first substrate surface 111 of the substrate 110. However, the embodiments are not limited thereto. The first substrate surface 111 of the substrate 110 may be disposed on a different plane from the surface of the device isolation portion 122 and/or the surface the isolation portion 130. The first substrate surface 111 of the substrate 110 may be on a different height from the surface of the device isolation portion 122 and/or the surface the isolation portion 130 in a thickness direction of the image sensor 10.

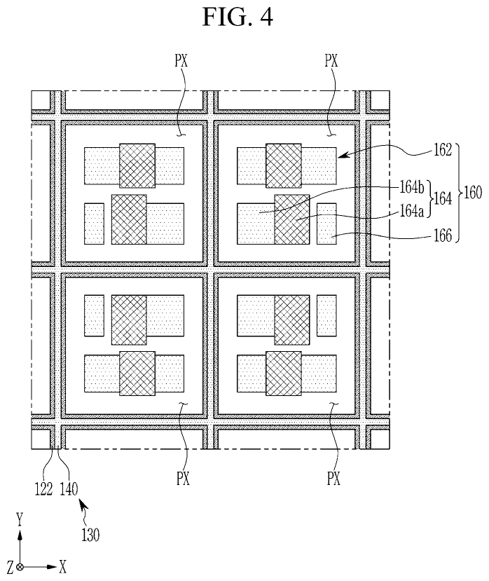

The pixel circuit 160 may be disposed to be adjacent to the first substrate surface 111 of the substrate 110. Referring to FIG. 4 together with FIG. 3, an example of the pixel circuit 160 may be described in detail. FIG. 4 is a rear plan view that illustrates a portion B of FIG. 2. FIG. 4 illustrates the pixel circuit 160 that is disposed on the first substrate surface 111 of the substrate 110.

Referring to FIG. 3 and FIG. 4, in some embodiments, the pixel circuit 160 may be disposed in the pixel region PX and/or the dummy pixel region DPX defined by the isolation portion 130 and/or the device isolation portion 122. For example, the pixel circuit 160 may include at least one transistor 162, a transfer transistor 164, and a dopant region 166. In FIG. 4, the pixel region PX is mainly illustrated. In some embodiments, the pixel circuit 160 illustrated in FIG. 4 may be disposed in the dummy pixel region DPX.

The transfer transistor 164 may be electrically connected to the photoelectric conversion portion 120. The transfer transistor 164 may include a transfer gate structure 164a and a floating diffusion region 164b. The floating diffusion region 164b may have a second conductivity type opposite to the first conductivity type of the substrate 110, and charges generated by the photoelectric conversion portion 120 may be accumulated in the floating diffusion region 164b. The floating diffusion region 164b may be adjacent to at least one side of the transfer gate structure 164a. A shape of the floating diffusion region 164b is not limited as illustrated in FIG. 4 and may be variously modified in some embodiments.

The transfer gate structure 164a may control the charges generated in the photoelectric conversion portion 120 to move or not to the floating diffusion region 164b or not to move depending on the applied voltage. The transfer gate structure 164a may include a transfer gate electrode, a gate dielectric layer, and/or a gate spacer.

The transistor 162 may include at least one of a reset transistor, a selection transistor, or a driving transistor included in the pixel circuit. The transistor 162 may include a gate structure and source and drain regions at both sides of the gate structure. For example, the transistors 162 of the plurality of pixel regions PX adjacent to each other may be shared to form the pixel circuit 160. In some embodiments, four pixel regions PX illustrated in FIG. 4 may be included in one unit pixel group, but the embodiments are not limited thereto. The pixel circuit 160 is an example, and the embodiments are not limited thereto. Accordingly, the pixel circuit 160 may have any of various structures or arrangements.

The dopant region 166 may be separated from the floating diffusion region 164b and the transistor 162. The dopant region 166 may be doped with a first conductivity type dopant to have the same conductivity type as the substrate 110, and a ground voltage may be applied to the dopant region 166.

Referring to FIG. 2 and FIG. 3 again, the wiring portion 170 that is electrically connected to the pixel circuit 160 may be disposed on the first substrate surface 111 of the substrate 110. That is, the wiring portion 170 may be disposed to be adjacent to the first substrate surface 111 of the substrate 110, which is opposite to the second substrate surface 112 of the substrate 110 to which the light is incident, and thus, the wiring portion 170 might not be disposed in a path of the light incident to the image sensor 10. Thereby, light interference caused by the wiring portion 170 may be minimized.

The wiring portion 170 may include a plurality of wiring layers 174 with an interlayer insulation layer 172 interposed therebetween, and a contact via 176 that passes through, penetrates, or extends into the interlayer insulation layer 172 to connect the plurality of wiring layer 174 or to connect the pixel circuit 160 and the wiring layer 174. The wiring layer 174 and the contact via 176 may be connected to form a desired circuit. The contact via 176 may be formed in the same process as the wiring layer 174, or may be formed in a separate process from the wiring layer 174.

The interlayer insulation layer 172 may include an insulating material. For example, the interlayer insulation layer 172 may include silicon oxide, silicon nitride, silicon oxynitride, or a low dielectric constant material. The low dielectric constant material may be a material having a dielectric constant lower than a dielectric constant of silicon oxide.

The wiring layer 174 or the contact via 176 may include at least one of a metal, a metal alloy, a metal nitride, a metal silicide, or a doped semiconductor material. The metal or the metal alloy may include at least one of tungsten, molybdenum, aluminum, copper, or cobalt, and the metal nitride may include at least one of tungsten nitride, molybdenum nitride, titanium nitride, or tantalum nitride. The wiring layer 174 or the contact via 176 may further include metal oxide or metal oxynitride in which the above material is oxidized. The wiring layer 174 or the contact via 176 may include a single layer or a plurality of layers.

However, the embodiments are not limited to thereto, and the interlayer insulation layer 172 may include any of various insulating materials, and the wiring layer 174 or the contact via 176 may include any of various conductive materials.

In some embodiments, the wiring portion 170 that is disposed on the first substrate surface 111 of the substrate 110 may include a connection wiring 178. The connection wiring 178 may be connected to the doping region 130d (e.g., a second doping region 150d (refer to FIG. 5)) that is disposed in the dummy region DA. This will be described later in more detail.

In the pixel array region 12, a horizontal insulation layer 180, a color filter 182, a filter separator 184, a protection layer 186, and a micro lens 188 may be disposed on the second substrate surface 112 of the substrate 110. In the dummy array region 14 of the substrate 110, the horizontal insulation layer 180, the optical black layer 190, the protection layer 186, a color filter layer 192, and an organic material layer 198 may be disposed on the second substrate surface 112 of the substrate 110.

More particularly, in the pixel array region 12 and the dummy array region 14, the horizontal insulation layer 180 may be disposed on the second substrate surface 112 of the substrate 110. The horizontal insulation layer 180 may be disposed to cover or overlap the second substrate surface 112 of the substrate 110 and the isolation portion 130. The horizontal insulation layer 180 may act as a kind of a planarization layer configured to planarize a surface so that the color filter 182, the micro lens 188, or so on disposed on the horizontal insulation layer 180 may be stably formed.

The horizontal insulation layer 180 may include any of various insulating materials. For example, the horizontal insulation layer 180 may include oxide, nitride, oxynitride, or fluoride including at least one of hafnium, zirconium, aluminum, tantalum, titanium, yttrium, cerium, lanthanum, neodymium, praseodymium, ytterbium, or silicon. For example, the horizontal insulation layer 180 may act as an anti-reflection layer, but the embodiments are not limited thereto.

In some embodiments, the horizontal insulation layer 180 may include a plurality of layers including different materials and having different thicknesses. For example, in the horizontal insulation layer 180, a first horizontal insulation layer adjacent to the second substrate surface 112 of the substrate 110 may be a fixed charge layer having a negative fixed charge. Thereby, the dark current may be improved by a hole accumulation at a periphery of the fixed charge layer. In some embodiments, the first horizontal insulation layer may include a metal oxide or metal fluoride including at least one of hafnium, zirconium, aluminum, tantalum, titanium, or yttrium. For example, the horizontal insulation layer 180 or the anti-reflection layer may include a first horizontal insulation layer including hafnium oxide, a second horizontal insulation layer including silicon oxide or silicon nitride, and a third horizontal insulation layer including hafnium oxide. However, the embodiments are not limited to thereto, and a number, a thickness, or so on of layers included in the horizontal insulation layer 180 may be variously modified.

In the pixel array region 12, the filter separator 184 may be disposed on the horizontal insulation layer 180. In some embodiments, the filter separator 184 may surround at least a partial portion of the color filter 182. For example, the filter separator 184 may have a lattice structure that is the same as or similar to the isolation portion 130, but the embodiments are not limited thereto. The filter separator 184 may be referred to as a fence pattern or a grid pattern.

The filter separator 184 may prevent light that is incident obliquely into one color filter 182 in one of the plurality of pixel regions PX from entering another color filter 182 in adjacent pixel region PX. Accordingly, a crosstalk between the plurality of pixel regions PX may be prevented.

In some embodiments, the filter separator 184 may include a material having a refractive index smaller than a refractive index of the color filter 182 or silicon oxide, or a material having a refractive index of about 1.0 to about 1.4. When the filter separator 184 includes a material with a small refractive index in the above, the light incident on the filter separator 184 may be totally reflected and directed toward an inside of the pixel region PX.

For example, the filter separator 184 may include polymethyl methacrylate (PMMA), silicon acrylate, cellulose acetate butyrate (CAB), silica, or fluorine-silicon acrylate (FSA). For example, the filter separator 184 may include a polymer material in which silica particles are dispersed. However, the embodiments are not limited to thereto, and the filter separator 184 may include a material different from the above material.

In the pixel array region 12, the color filter 182 may be disposed on the horizontal insulation layer 180. A plurality of color filters 182 may include, for example, a green filter, a blue filter, and a red filter. In some embodiments, the plurality of color filters 182 may include a cyan filter, a magenta filter, a yellow filter, or so on. In some embodiments, a pixel region PX where all visible light is incident may be provided. In some embodiments, the color filter 182 may further include an infrared filter for transmitting infrared light. The plurality of color filters 182 may be separated from each other by the filter separator 184.

In at least a partial portion of the dummy array region 14, the optical black layer 190 may be disposed on the horizontal insulation layer 180. The optical black layer 190 may cover or overlap an entire portion of the dummy array region 14, or cover or overlap a partial portion of the dummy array region 14. For example, the optical black layer 190 may cover or overlap the first dummy array region 14a in which the dummy pixel region DPX including at least the photoelectric conversion portion 120 and/or the pixel circuit 160 is disposed. The optical black layer 190 may cover or overlap or might not cover or might not overlap the second dummy array region 14b in which the dummy region DA is disposed.

The optical black layer 190 may include a metal material, and may include a single layer or a plurality of layers. The optical black layer 190 may correspond to a light blocking pattern or a light shielding pattern that blocks light incident on at least a partial portion of the dummy array region 14.

For example, the optical black layer 190 may include a metal layer that includes at least one of tungsten, aluminum, copper, titanium, or tantalum, or an alloy including the same. The optical black layer 190 may further include a diffusion barrier layer between the horizontal insulation layer 180 and the metal layer. The diffusion barrier layer may include a metal nitride layer that includes titanium nitride, tantalum nitride, tungsten nitride, or so on. However, the embodiments are not limited thereto, and the optical black layer 190 may include any of various materials or have any of various stacking structures.

In some embodiments, the optical black layer 190 (e.g., the metal layer included in the optical black layer 190) might not be electrically connected to another portion (e.g., the wiring portion 170, the pad 210, or the conductive layer 134 included in the isolation portion 130). Accordingly, the optical black layer 190 may include an insulating material capable of blocking light. In some embodiments, if light may be sufficiently blocked using the color filter layer 192 and/or other portions, the metal layer or the diffusion barrier layer of the optical black layer 190 may be omitted.

In some embodiments, in the pixel array region 12 and/or the dummy array region 14, the protection layer 186 may be disposed on the horizontal insulation layer 180, the filter separator 184, and/or the optical black layer 190. The protection layer 186 may be disposed between the horizontal insulation layer 180 and the color filter 182, between the filter separator 184 and the color filter 182, and/or between the optical black layer 190 and the color filter layer 192. For example, the protection layer 186 may extend on an upper surface of the horizontal insulation layer 180, on a side surface and an upper surface of the filter separator 184, and/or on an upper surface of the optical black layer 190. For example, the protection layer 186 may include aluminum oxide, but the embodiments are not limited thereto. The protection layer 186 may prevent damage of the horizontal insulation layer 180, the filter separator 184, and/or the optical black layer 190.

In the pixel array region 12, the micro lens 188 may be disposed on the filter separator 184, the protection layer 186, and/or the color filter 182. The micro lens 188 may include or be formed of a portion having a convex shape to converge or concentrate light incident to the pixel region PX. The micro lens 188 may include any or various resin materials, for example, a styrene-based resin, an acryl-based resin, a styrene-acryl copolymer resin, a siloxane-based resin, or so on. However, the embodiments are not limited to thereto, and a shape, a material, or so on of the micro lens 188 may be variously modified.

In FIG. 3, it is illustrated that a plurality of micro lens 188 correspond to a plurality of pixel regions PX, respectively. However, the embodiments are not limited to thereto, and one micro lens 188 may correspond to a plurality of pixel regions PX. In some embodiments, an outer protection layer or so on may be further disposed on an outer surface of the micro lens 188.

In the dummy array region 14, the color filter layer 192 may be disposed on the optical black layer 190. For example, the color filter layer 192 may be disposed on the protection layer 186 that is disposed on the optical black layer 190 in the dummy array region 14. For example, the color filter layer 192 may include a blue filter, but the embodiments are not limited thereto.

In the dummy array region 14, the organic material layer 198 may be disposed on the color filter layer 192. The organic material layer 198 may include a light transmitting material (e.g., a light transmitting resin), but the embodiments are not limited thereto. In some embodiments, the organic material layer 198 may include a material that is the same as a material of the micro lens 188.

In some embodiments, in a plan view, a relative position between the pixel region PX and the color filter 182 and/or a relative position between the pixel region PX and the micro lens 188 may be different from each other in a central portion of the pixel array region 12 and in an edge portion of the pixel array region 12. That is, in a plan view, an area (e.g. a planar area) of the color filter 182 that overlaps the pixel region PX and/or an area (e.g. a planar area) of the micro lens 188 that overlaps the pixel region PX may be smaller in the edge region of the pixel array region 12 than in the central region of the pixel array region 12. For example, an area (e.g. a planar area) of the color filter 182 that overlaps the pixel region PX and/or an area (e.g. a planar area) of the micro lens 188 that overlaps the pixel region PX may decrease from the central region of the pixel array region 12 to the edge region of the pixel array region 12.

By adjusting the relative position between the pixel region PX and the color filter 182 and/or the relative position between the pixel region PX and the micro lens 188, an amount of the light that reaches the photoelectric conversion portion 120 of the pixel region PX may be maximized. For example, the micro lens 188, the color filter 182, and the photoelectric conversion portion 120 of the pixel region PX may be disposed to be overlapped in a direction where light passes. Since the light is incident obliquely in the edge region of the pixel array region 12, the relative position of the pixel region PX, the color filter 182, and/or the micro lens 188 may be adjusted so that the light that is incident obliquely can reach the photoelectric conversion portion 120 of the pixel region PX to a large amount.

In FIG. 2, it is illustrated as an example that the dummy pixel region DPX in the dummy array region 14 includes a first dummy pixel region. The first dummy pixel region may include the photoelectric conversion portion 120 and the pixel circuit 160. However, the embodiments are not limited thereto. The dummy pixel region DPX may further include a second dummy pixel region. The second dummy pixel region may include at least a partial portion of the pixel circuit 160 and might not include the photoelectric conversion portion 120. The first dummy pixel region may provide a first reference charge amount when light is blocked. The first reference charge amount may be a relative reference when the amount of charges generated from the pixel area PX is calculated. The second dummy pixel region may provide a second reference charge amount when the photoelectric conversion portion 120 is not included. The second reference charge amount may be used as information configured to remove process noise.

In some embodiments, the additional wiring portion 200 may include the pad 210, and may further include a semiconductor substrate 220, a circuit element 230 (e.g., a transistor), a logic circuit portion, a power supply portion, a wiring 240, or so on. The pad 210 may be disposed in the pad region 16. The wiring 240 of the additional wiring portion 200 may include an interlayer insulation layer, a wiring layer, a contact via, or so on. A description of the interlayer insulation layer 172, the wiring layer 174, or the contact via 176 that is included in the wiring portion 170 may be applied to the interlayer insulation layer, the wiring layer, or the contact via that is included in the wiring 240 of the additional wiring portion 200. However, the embodiments are not limited thereto, and a member included in the additional wiring portion 200 may be variously modified. The pad 210 may be a portion configured to be electrically connected to the external circuit, or so on. For example, the pad 210 may be connected to the external circuit, or so on using wire bonding or so on, but the embodiments are not limited thereto. The pad 210 may be electrically connected to the wiring portion 170 of the photoelectric conversion substrate 100. For example, the pad 210 may be electrically connected to the connection wiring 178 that is included in the wiring portion 170. In the pad region 16, a recess portion 212 that passes through, extends into, or penetrates partial portions of the photoelectric conversion substrate 100 and the additional wiring portion 200 to expose the pad 210 may be disposed.

In some embodiments, the pad 210 and the wiring portion 170 may be

disposed to be adjacent to the first substrate surface 111 of the substrate 110, and thus, the image sensor 10 may have relatively small parasitic capacitance, compared to a comparative example in which a pad is disposed on a second substrate surface of a substrate.

The additional wiring portion 200 may be electrically connected to the wiring portion 170 that is included in the photoelectric conversion substrate 100. The additional wiring portion 200 may be bonded to the photoelectric conversion substrate 100 at the first surface 101 of the photoelectric conversion substrate 100. In some embodiments, the wiring portion 170 of the photoelectric conversion substrate 100 and the additional wiring portion 200 may be bonded by hybrid bonding including metal bonding and insulation-layer bonding. In some embodiments, the wiring portion 170 of the photoelectric conversion substrate 100 and the additional wiring portion 200 may be bonded by insulation-layer bonding, and then, a connection member or so on configured to connect the wiring portion 170 and the additional wiring portion 200 may be formed. Other various modifications are possible.

When the photoelectric conversion substrate 100 and the additional wiring portion 200 are included as in the above, congestion of wirings, circuit elements, or so on that are included in the wiring portion 170 of the photoelectric conversion substrate 100 and the additional wiring portion 200 may be reduced. As a result, an area (e.g., a planar area) of the pixel region PX of the image sensor 10 may be reduced and thus an integration degree and properties of the image sensor 10 may be enhanced.

In FIG. 3, it is illustrated as an example that the image sensor 10 includes the photoelectric conversion substrate 100 and the additional wiring portion 200 that includes the pad 210. However, the embodiments are not limited thereto. The wiring portion 170 that is included in the photoelectric conversion substrate 100 may include the pad 210. In this instance, the pad 210 may be included in the wiring portion 170 that is disposed on the first substrate surface 111 of the substrate 110 and thus may be adjacent to the first substrate surface 111 of the substrate 110. In some embodiments, the wiring portion 170 that is included in the photoelectric conversion substrate 100 may include the circuit element 230 (e.g., the transistor), the logic circuit portion, the power supply portion, the wiring 240, or so on that is included in the additional wiring portion 200. In this instance, the image sensor 10 may be formed of the photoelectric conversion substrate 100 that includes the wiring portion 170, and the additional wiring portion 200 may be omitted.

Referring to FIG. 4 to FIG. 6 together with FIG. 2 and FIG. 3, the isolation portion 130, the doping region 130d, and the connection wiring 178 that is connected to the doping region 130d will be described in detail.

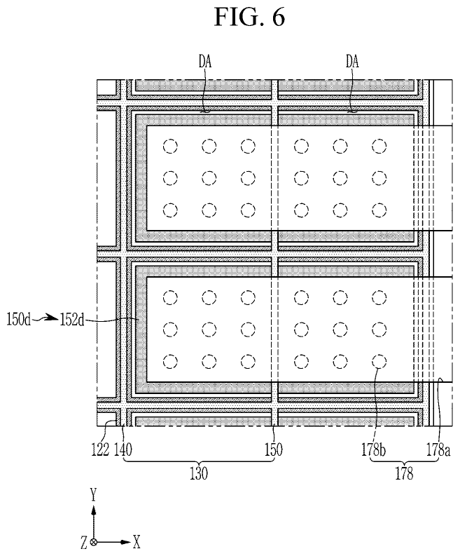

FIG. 5 is a cross-sectional view that illustrates a portion C of FIG. 3. FIG. 6 is a rear plan view that illustrates a portion D of FIG. 2. FIG. 6 illustrates the connection wiring 178 that is disposed on the first substrate surface 111 of the substrate 110.

Referring to FIG. 2 to FIG. 6, in some embodiments, the isolation portion 130 may include a first isolation portion 140, and a second isolation portion 150 that has a depth less than a depth of the first isolation portion 140. The depth of the first isolation portion 140 or the depth of the second isolation portion 150 may refer to a depth in a thickness direction of the image sensor 10 or a vertical direction that is perpendicular to the image sensor 10, for example, a maximum depth. The doping region 130d may include a first doping region 140d that is disposed at a periphery of the first isolation portion 140 and a second doping region 150d that is disposed at a periphery of the second isolation portion 150. The first doping region 140d and the second doping region 150d may have different shapes.

The first isolation portion 140 may be disposed at least in the pixel array region 12 to define the pixel region PX. For example, the first isolation portion 140 may be disposed at a boundary of the pixel region PX and/or a boundary of the dummy pixel region DPX in the pixel array region 12 and/or the dummy array region 14.

The second isolation portion 150 may be disposed at least at a part of a boundary of the plurality of dummy regions DA. In FIG. 2, it is illustrated as an example that the second isolation portion 150 is disposed to correspond to a part of the boundary of the dummy region DA and the first isolation portion 140 is disposed to correspond to another part of the boundary of the dummy region DA. For example, at least a part of the isolation portion 130 that is disposed to correspond to a boundary between two adjacent dummy regions DA may include the second isolation portion 150, and the isolation portion 130 that is disposed to correspond to a boundary between the dummy region DA and the dummy pixel region DPX may include the first isolation portion 140. In FIG. 2, it is illustrated as an example that, in the isolation portion 130 that is disposed to correspond to a boundary between two adjacent dummy regions DA, a partial portion is formed of the second isolation portion 150 and the other portion is formed of the first isolation portion 140.

The first isolation portion 140 may pass through, extend into, or penetrate at least a partial portion of the substrate 110. In some embodiments, in the thickness direction of the image sensor 10 (the Z-axis direction in the drawings) or the vertical direction, a first end 1401 of the first isolation portion 140 may be adjacent to the first substrate surface 111 and a second end 1402 of the first isolation portion 140 may be adjacent to the second substrate surface 112. For example, the first end 1401 of the first isolation portion 140 may pass through, extend into, or penetrate the first substrate surface 111, and the second end 1402 of the first isolation portion 140 may pass through, extend into, or penetrate the second substrate surface 112. However, the embodiments are not limited thereto, and at least one of the first end 1401 and the second end 1402 of the first isolation portion 140 may be spaced apart from the first substrate surface 111 or the second substrate surface 112.

The first isolation portion 140 may include a first sidewall insulation layer 142 and a first conductive portion 144 disposed on the first sidewall insulation layer 142, and may further include a first capping portion 146. The first sidewall insulation layer 142 may include a first insulation portion 142a and a second insulation portion 142b. The first conductive portion 144 may be disposed between the first insulation portion 142a and the second insulation portion 142b of the first sidewall insulation layer 142. The first capping portion 146 may be disposed between the first insulation portion 142a and the second insulation portion 142b of the first sidewall insulation layer 142 on the first conductive portion 144 to be adjacent to the first substrate surface 111 of the substrate 110.

In the thickness direction of the image sensor 10 (the Z-axis direction in the drawings) or the vertical direction, the first insulation portion 142a and the second insulation portion 142b of the first sidewall insulation layer 142 and/or at least a partial portion of the first capping portion 146 may be adjacent to the first substrate surface 111 of the substrate 110. In the thickness direction of the image sensor 10 (the Z-axis direction in the drawings) or the vertical direction, the first insulation portion 142a and the second insulation portion 142b of the first sidewall insulation layer 142, and at least a partial portion of the first conductive portion 144 may be adjacent to the second substrate surface 112 of the substrate 110.

The first doping region 140d may include a first doping portion 141d that is disposed on a side surface of the first isolation portion 140. For example, first doping regions 140d or first doping portions 141d may be disposed at both side surfaces of the first isolation portion 140. The first doping portion 141d may be formed by performing a process of doping a dopant to a portion adjacent to a surface of a first trench 140t after forming the first trench 140t configured to form the first isolation portion 140.

In a plan view, the first conductive portion 144 in one first isolation portion 140 may be connected (e.g., mechanically and/or electrically connected) to the first conductive portion 144 in another first isolation portion 140 and/or the second conductive portion 154 in the second isolation portion 150 that is connected to the one first isolation portion 140.

In a cross-section (an XZ plane or a YZ plane) perpendicular to an extension direction of the first isolation portion 140, an entire portion of the first conductive portion 144 may be spaced apart from or electrically isolated from the substrate 110 or the first doping region 140d. For example, in the cross-section perpendicular to the extension direction of the first isolation portion 140, both side surfaces of the first conductive portion 144 may be electrically isolated or insulated by the first insulation portion 142a and the second insulation portion 142b of the first sidewall insulation layer 142, the first end 1401 of the first conductive portion 144 may be electrically isolated or insulated by the first capping portion 146, and the second end 1402 of the first conductive portion 144 may be electrically isolated or insulated by the horizontal insulation layer 180. However, the embodiments are not limited thereto, and at least a partial portion of the first conductive portion 144 may be electrically isolated or insulated by other insulation layer or other insulation portion that is different from the first sidewall insulation layer 142, the first capping portion 146, and the horizontal insulation layer 180.

The second isolation portion 150 may pass through, extend into, or penetrate a partial portion of the substrate 110. In some embodiments, in the thickness direction of the image sensor 10 (the Z-axis direction in the drawings) or the vertical direction, a first end 1501 of the second isolation portion 150 may be adjacent to the first substrate surface 111 and a second end 1502 of the second isolation portion 150 may be spaced apart from the second substrate surface 112. For example, the first end 1501 of the second isolation portion 150 may pass through or penetrate the first substrate surface 111, and the second end 1502 of the second isolation portion 150 may be disposed inside or extends into the substrate 110.

The second isolation portion 150 may include a second sidewall insulation layer 152 and a second conductive portion 154 disposed on the second sidewall insulation layer 152, and may further include a second capping portion 156. The second sidewall insulation layer 152 may include a first insulation portion 152a and a second insulation portion 152b. The second conductive portion 154 may be disposed between the first insulation portion 152a and the second insulation portion 152b of the second sidewall insulation layer 152. The second capping portion 156 may be disposed between the first insulation portion 152a and the second insulation portion 152b of the second sidewall insulation layer 152 on the second conductive portion 154 to be adjacent to the first substrate surface 111 of the substrate 110.

In the thickness direction of the image sensor 10 (the Z-axis direction in the drawings) or the vertical direction, the first insulation portion 152a and the second insulation portion 152b of the second sidewall insulation layer 152 and/or at least a partial portion of the second capping portion 156 may be adjacent to the first substrate surface 111 of the substrate 110. In the thickness direction of the image sensor 10 (the Z-axis direction in the drawings) or the vertical direction, the first insulation portion 152a and the second insulation portion 152b of the second sidewall insulation layer 152, and at least a partial portion of the second conductive portion 154 may be spaced apart from the second substrate surface 112 of the substrate 110. For example, in the second end 1502, the first insulation portion 152a and the second insulation portion 152b of the second sidewall insulation layer 152, and the second conductive portion 154 may be disposed inside or extends into the substrate 110. The second end 1502 that is disposed inside or extends into the substrate 110 may be a conductive end to which the conductive layer 134 (e.g., the second conductive portion 154) is exposed to allow an electrical connection with another portion.

The second doping region 150d may include a first doping portion 151d and a second doping portion 152d, and may further include a base doping portion 154d.

The first doping portion 151d of the second doping region 150d may be disposed on a side surface of the second isolation portion 150 and on the second end 1502. For example, the first doping portion 151d of the second doping region 150d may be disposed to surround an entire portion of both side surfaces of the second isolation portion 150 and the second end 1502. The first doping portion 151d of the second doping region 150d may be electrically connected to the second end 1502 of the second isolation portion 150. That is, the first doping portion 151d of the second doping region 150d may be electrically connected to the conductive end.

The second doping portion 152d may be formed by performing a process of doping a dopant to a portion adjacent to a surface of a second trench 150t after forming the second trench 150t configured to form the second isolation portion 150. The first doping portion 151d of the second doping region 150d and the first doping portion 141d of the first doping region 140d may be formed by a same doping process. However, the embodiments are not limited thereto, and the first doping portion 151d of the second doping region 150d and the first doping portion 141d of the first doping region 140d may be formed by different processes.

The second doping portion 152d may be adjacent to the first substrate surface 111 of the substrate 110 and be connected to the first doping portion 151d. The second doping portion 152d may be formed by performing a process of doping a dopant to the dummy region DA. The second doping portion 152d may be formed by a separate process from a process of forming the first doping portion 141d of the first doping region 140d and/or the first doping portion 151d of the second doping region 150d. The second doping portion 152d may be disposed in the dummy region DA that is adjacent to the second isolation portion 150 and might not be disposed in the pixel region PX and/or the dummy pixel region DPX.

For example, a doping concentration of the second doping portion 152d may be less than a doping concentration of the first doping portion 151d. The doping concentration may refer to an average doping concentration or a lowest doping concentration. By a relatively high doping concentration of the first doping portion 151d, a dark current may be effectively improved. However, the embodiments are not limited thereto. In some embodiments, the doping concentration of the second doping portion 152d may be the same as or higher than the first doping portion 151d. Thereby, electrical resistance of the second doping portion 152d and the connection wiring 178 may be reduced.

The base doping portion 154d may have a doping concentration less than the doping concentration of the first doping portion 151d or the second doping portion 152d. The base doping portion 154d may be adjacent to the first substrate surface 111 of the substrate 110 and may be disposed in a portion deeper than the second doping portion 152d. The base doping portion 154d may be formed by a same process as a process of forming the first conductivity type well 120b that is disposed in the pixel region PX and/or the dummy pixel region DPX and has the first conductivity type. However, the embodiments are not limited thereto. The base doping portion 154d may be formed by a different process from the process of forming the first conductivity type well 120b that is disposed in the pixel region PX and/or the dummy pixel region DPX.

In some embodiments, in the dummy region DA, the pixel circuit 160 might not be disposed to be adjacent to the first substrate surface 111 of the substrate 110. The second doping region 150d (e.g., the second doping portion 152d) may be disposed to have a relatively large area in the dummy region DA. For example, at a portion adjacent to the first substrate surface 111, in an entire portion of the dummy region DA, an area of a portion where the second doping region 150d is disposed may be greater than an area of another portion where the second doping region 150d is not disposed. At the portion adjacent to the first substrate surface 111, an area of the second doping region 150d (e.g., the second doping portion 152d) that is disposed in the dummy region DA may be greater than an area of the dopant region 166 that is disposed in the pixel region PX and/or the dummy pixel region DPX including the pixel circuit 160 and has the first conductivity type. Thereby, an electrical connection area between the second doping region 150d and the connection wiring 178 may increase and thus the second doping region 150d and the connection wiring 178 may be stably electrically connected to each other.

In FIG. 6, it is illustrated as an example that the device isolation portion 122 is disposed at a portion where the first isolation portion 140 is disposed, and the device isolation portion 122 is not disposed at a portion where the second isolation portion 150 is disposed. The first isolation portion 140 may pass through or penetrate a partial portion (e.g., a central portion) of the device isolation portion 122.

When the device isolation portion 122 is not disposed at the portion where the second isolation portion 150 is disposed as in the above, the second isolation portion 150 that has the depth less than the depth of the first isolation portion 140 may be formed by an easy process. This will be described later in more detail in a manufacturing method of an image sensor 10. However, the embodiments are not limited thereto, and the device isolation portion 122 may be disposed at the portion where the second isolation portion 150 is disposed.

In a plan view, the second conductive portion 154 in one second isolation

portion 150 may be connected (e.g., mechanically and/or electrically connected) to the first conductive portion 144 in the first isolation portion 140 and/or the second conductive portion 154 in another second isolation portion 150 that is connected to the one second isolation portion 150.

The second conductive portion 154 that is disposed in the second isolation portion 150 may include a portion that is electrically connected to the substrate 110 (e.g., the second doping region 150d that is disposed at the periphery of the second isolation portion 150). In a cross-section (an XZ plane or a YZ plane) that is perpendicular to an extension direction of the second isolation portion 150, the second conductive portion 154 may be electrically connected to the second doping region 150d. For example, the second conductive portion 154 that is disposed at the second end 1502 inside or extending into the substrate 110 may be connected to the substrate 110 or the second doping region 150d. More particularly, an end of the second conductive portion 154 that is disposed at the second end 1502 may be connected (e.g., mechanically and/or electrically connected) to the second doping portion 152d. The second conductive portion 154 that is disposed at the second end 1502 may be directly connected to or in contact with the second doping portion 152d. For example, in the cross-section that is perpendicular to the extension direction of the second isolation portion 150, both side surfaces of the second conductive portion 154 may be electrically isolated or insulated by the first insulation portion 152a and the second insulation portion 152b of the second sidewall insulation layer 152, and the second conductive portion 154 at the first end 1501 may be electrically isolated or insulated by the second capping portion 156.

However, the embodiments are not limited thereto. In some embodiments, the second conductive portion 154 may be connected to the substrate 110 or the second doping region 150d at a position different from the second end 1502, or the second conductive portion 154 may be connected to a portion other than the first doping portion 151d of the second doping region 150d. In some embodiments, the second conductive portion 154 may be connected to the substrate 110 or the second doping region 150d through another member or portion. In some embodiments, at least a partial portion of the second conductive portion 154 may be electrically isolated or insulated by other insulation layer or other insulation portion that is different from the second sidewall insulation layer 152 or the second capping portion 156.

In some embodiments, the entire portion of the first conductive portion 144 that is disposed in the first isolation portion 140 may electrically insulated and the first conductive portion 144 might not be directly connected to the first doping region 140d. However, the first conductive portion 144 that is disposed in the first isolation portion 140 may be electrically connected to the doping region 130d through the second conductive portion 154 that is disposed in the second isolation portion 150.

In FIG. 5, it is illustrated as an example that the depth of the second isolation portion 150 is greater than a thickness of the second doping portion 152d, and a depth of the second isolation portion 150 may be greater than the depth of the base doping portion 154d. The thickness of the second doping portion 152d may refer to a minimum thickness between the first substrate surface 111 and an inner surface of the second doping portion 152d that is adjacent to the first substrate surface 111, and the depth of the base doping portion 154d may refer to a minimum depth between the first substrate surface 111 and an inner surface of the base doping portion 154d that is adjacent to the first substrate surface 111. Thereby, the second isolation portion 150 may be formed to have a stable depth. However, the embodiments are not limited thereto. The depth of the second isolation portion 150 may be the same as or less than the thickness of the second doping portion 152d, and/or the depth of the second isolation portion 150 may be the same as or less than the depth of the base doping portion 154d.

In some embodiments, the wiring portion 170 that is disposed on the first substrate surface 111 of the substrate 110 may include the connection wiring 178 that is electrically connected to the doping region 130d (e.g., the second doping region 150d). That is, the connection wiring 178 that is connected to the doping region 130d (e.g., the second doping region 150d) may be disposed on the first substrate surface 111 of the substrate 110.

The connection wiring 178 may be a voltage-applying wiring (e.g. a negative-voltage-applying wiring) that applies a voltage (e.g. a negative voltage) to the second conductive portion 154 that is disposed in the second isolation portion 150. The connection wiring 178 may include a connection wiring layer 178a and a connection contact via 178b that connects (e.g., directly connects) the connection wiring layer 178a and the second doping region 150d (e.g., the second doping portion 152d).

The connection wiring 178 may be a part of the wiring layer 174 that is included in the wiring portion 170 and the connection contact via 178b that is included in the wiring portion 170. The connection wiring layer 178a or the connection contact via 178b may include a material that is the same as a material of the wiring layer 174 or the contact via 176. Description of the material of the wiring layer 174 or the contact via 176 may be applied to the material of the connection wiring layer 178a or the connection contact via 178b as is. For example, a material of the connection contact via 178b may have electrical conductivity higher than electrical conductivity of a material of the connection wiring layer 178a. Thereby, contact electrical resistance of the second doping region 150d and the connection wiring 178 by reducing electrical resistance of the connection contact via 178b. However, the embodiments are not limited thereto, and the material of the connection contact via 178b may have electrical conductivity the same as or lower than electrical conductivity of a material of the connection wiring layer 178a.

As such, the connection wiring 178 that is electrically connected to the second doping region 150d in the dummy region DA may be disposed on the first substrate surface 111 of the substrate 110, like the wiring portion 170 or the pad 210. Accordingly, a voltage may be applied to the conductive layer 134 that is disposed in the isolation portion 130 without a substrate through via that passes through, extends into, or penetrates the substrate 110. That is, the connection wiring 178 may apply a voltage the first conductive portion 144 that is disposed in the first isolation portion 140 through the second doping region 150d and the second conductive portion 154 of the second isolation portion 150.

Referring to FIG. 2, in some embodiments, the second isolation portion 150 may include a first extension portion 150a and a second extension portion 150b. The first extension portion 150a may extend in the first direction (the Y-axis direction in the drawings), and the second extension portion 150b may extend in the second direction (the X-axis direction in the drawings) that is transverse to (e.g., is perpendicular to) the first direction.

The first extension portion 150a of the second isolation portion 150 may extend in the first direction (the Y-axis direction in the drawings) to correspond to a boundary between a plurality of first dummy regions DA1 and a plurality of second dummy regions DA2. The plurality of first dummy regions DA1 may be adjacent to each other in the first direction, the plurality of second dummy regions DA2 may be adjacent to each other in the first direction, and the plurality of second dummy regions DA2 may be adjacent to the plurality of first dummy regions DA1, respectively, in the second direction (the X-axis direction in the drawings). That is, a plurality of first portions that are disposed to correspond to the boundary between the first dummy regions DA1 and the second dummy regions DA2 in an edge portion in the second direction may include the first extension portions 150a.

The second extension portion 150b of the second isolation portion 150 may extend in the second direction (the X-axis direction in the drawings) to correspond to a boundary between a plurality of third dummy regions DA3 and a plurality of fourth dummy regions DA4. The plurality of third dummy regions DA3 may be adjacent to each other in the second direction, the plurality of fourth dummy regions DA4 may be adjacent to each other in the second direction, and the plurality of fourth dummy regions DA4 may be adjacent to the plurality of third dummy regions DA3, respectively, in the first direction (the Y-axis direction in the drawings). That is, a plurality of second portions that are disposed to correspond to the boundary between the third dummy regions DA3 and the fourth dummy regions DA4 in an edge portion in the first direction may include the second extension portion 150b.

In FIG. 2, it is illustrated as an example that first extension portions 150a extending in the first direction (the Y-axis direction in the drawings) are disposed at both sides of the second direction (the X-axis direction in the drawings), respectively, second extension portions 150b extending in the second direction are disposed at both sides of the first direction, respectively, and the first extension portions 150a and the second extension portions 150b are connected to each other. Accordingly, the second isolation portion 150 may have a shape (e.g., a rectangular shape) that surrounds an entire portion of the pixel array region 12, thereby uniformly applying a negative voltage to the pixel array region 12. However, the embodiments are not limited thereto. A position, a shape, or so on of the second isolation portion 150 may be variously modified.

In FIG. 2, it is illustrated as an example that the first extension portion 150a longitudinally extends to correspond to a boundary between the plurality of first dummy regions DA1 and the plurality of second dummy regions DA2 to correspond to an entire portion of an edge of the pixel array region 12. In FIG. 2, it is illustrated as an example that the second extension portion 150b longitudinally extends to correspond to a boundary between the plurality of third dummy regions DA3 and the plurality of fourth dummy regions DA4 to correspond to an entire portion of an edge of the pixel array region 12. In FIG. 2, it is illustrated as an example that the first extension portions 150a disposed at both sides of the pixel array region 12, respectively, have a same or symmetric shape, and the second extension portions 150b disposed at both sides of the pixel array region 12, respectively, have a same or symmetric shape. However, the embodiments are not limited thereto.

In some embodiments, the first extension portion 150a and/or the second extension portion 150b may be disposed at a partial portion of an edge, the first extension portion 150a may be disposed to correspond to a boundary between one first dummy region DA1 and one second dummy region DA2, or the second extension portion 150b may be disposed to correspond to a boundary between one third dummy region DA3 and one fourth dummy region DA4. In some embodiments, a plurality of first extension portions 150a and/or a plurality of second extension portions 150b may be provided near one edge of the pixel array region 12. In some embodiments, the first extension portions 150a disposed at both sides of the pixel array region 12, respectively, may be disposed at different positions or may have different shapes, or the second extension portions 150b disposed at both sides of the pixel array region 12, respectively, may be disposed at different positions or may have different shapes.

In FIG. 2, it is illustrated as an example that an interval between two first isolation portions 140 is the same as an interval between the first isolation portion 140 and the second isolation portion 150. However, the embodiments are not limited thereto. In some embodiments, an interval between two first isolation portions 140 may be greater than an interval between the first isolation portion 140 and the second isolation portion 150. By reducing the interval between the first isolation portion 140 and the second isolation portion 150, an area (e.g., a planar area) of the second dummy array region 14b may be reduced. Thereby, an area (e.g., a planar area) of the image sensor 10 may be reduced. In some embodiments, an interval between two first isolation portions 140 may be smaller than an interval between the first isolation portion 140 and the second isolation portion 150. By increasing the interval between the first isolation portion 140 and the second isolation portion 150, an area (e.g., a planar area) of the second dummy array region 14b may be sufficiently secured. Accordingly, by sufficiently securing the area of the second doping portion 152d, a connection area with the connection wiring 178 may increase to enhance an electrical connection property.

According to some embodiments, the second doping region 150d that is electrically connected to the second conductive portion 154 in the second isolation portion 150 in the substrate 110 may be used to enhance a dark current. For example, by applying a voltage (e.g., a negative voltage) to the isolation portion 130 through the connection wiring 178 that is connected to the second doping region 150d, the dark current may be enhanced through a hole accumulation.

The connection wiring 178 may be included in the wiring portion 170 that is disposed to be adjacent to the first substrate surface 111 of the substrate 110 and thus a path for applying the voltage to the isolation portion 130 may be reduced and the image sensor 10 may be manufactured by an easy process. Accordingly, performance of the image sensor 10 may be enhanced by effectively applying the voltage to the isolation portion 130, and productivity and yield of the image sensor 10 may be enhanced by simplifying a manufacturing process and reducing a process error.

According to some embodiments, in a comparative example in which a wiring portion is disposed to be adjacent to a first substrate surface of a substrate and a negative-voltage-applying wiring configured to apply a negative voltage to an isolation portion is disposed to be adjacent to a second substrate surface of the substrate, a process of forming the negative-voltage-applying wiring to be adjacent to the second substrate surface and a process of forming a substrate through via are performed. The substrate through via passes through, extends into or penetrates the substrate for an electrical connection between the negative-voltage-applying wiring that is adjacent to the second substrate surface and the wiring portion that is adjacent to the first substrate surface. Accordingly, a manufacturing process is complicated, and process errors may increase due to generation of unwanted particles in the process of forming the substrate through via. Further, a path to apply the negative voltage is long and the electrical resistance is thus higher, and thus it may be difficult to effectively apply the negative voltage. In another comparative example that includes a contact plug or so on passing through, extending into, or penetrating a partial portion of an isolation portion, an additional process of forming a through via that passes through or penetrates the partial portion of the isolation portion is performed. Accordingly, properties of the isolation portion may be deteriorated, or deviation or distribution of the manufacturing process may be large. As a result, reliability and productivity may be reduced.

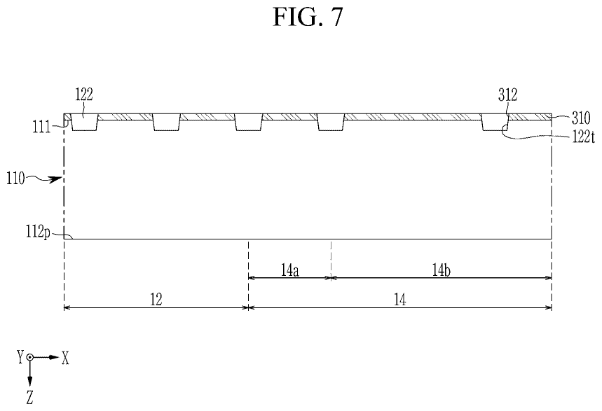

A manufacturing method of an image sensor 10 will be described in detail with reference to FIG. 7 to FIG. 16.

FIG. 7 to FIG. 16 are cross-sectional views that schematically illustrate a manufacturing method of an image sensor 10 according to some embodiments. FIG. 7 to FIG. 16 illustrate portions that correspond to a pixel array region 12 and a dummy array region 14.

As illustrated in FIG. 7, a device isolation portion 122 may be formed at a first substrate surface 111 of a substrate 110 that includes the first substrate surface 111 and a preliminary surface 112p opposite to each other.

For example, a mask pattern 310 may be formed on the first substrate surface 111 of the substrate 110. The mask pattern 310 may have an opening 312 that exposes a region corresponding to the device isolation portion 122. The mask pattern 310 may include any of various insulating materials, for example, silicon nitride. For a patterning process of forming the opening of the mask pattern 310, any of various processes may be used, for example, a photolithography process.

A shallow trench 122t may be formed by etching a part of the substrate 110 that is exposed through the opening 312 of the mask pattern 310. For an etching process, various processes such as a dry etching process, a dry etching process, or so on may be used.

The device isolation portion 122 may be formed at a portion adjacent to the first substrate surface 111 of the substrate 110 by filling an insulating material layer in the shallow trench 122t. In some embodiments, the device isolation portion 122 may be formed by forming the insulating material layer inside the shallow trench 122t and on the mask pattern 310 and then removing a part of the insulating material layer that is disposed on the mask pattern 310. In some embodiments, the device isolation portion 122 may be formed by partially forming an insulating material layer to fill the shallow trench 122t.

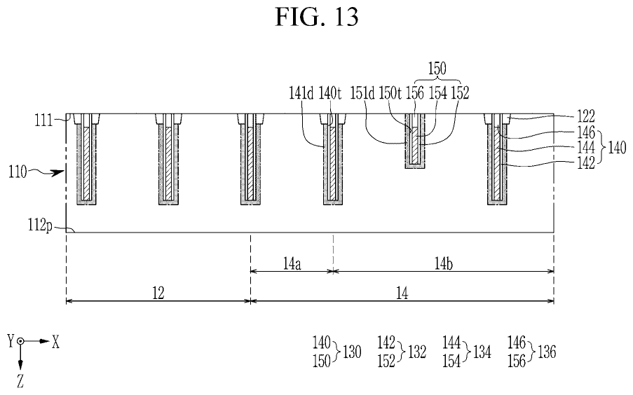

In some embodiments, the device isolation portion 122 may be disposed to correspond to a portion in which a first isolation portion 140 (refer to FIG. 13) will be disposed. The device isolation portion 122 might not be disposed in a portion in which a second isolation portion 150 (refer to FIG. 13) will be disposed. Accordingly, an insulating material (e.g., silicon oxide) that is included in the device isolation portion 122 may be disposed at a portion where the first isolation portion 140 will be formed, and an insulating material (e.g., silicon nitride) that is included in the mask pattern 310 may be disposed at a portion where the second isolation portion 150 will be formed.

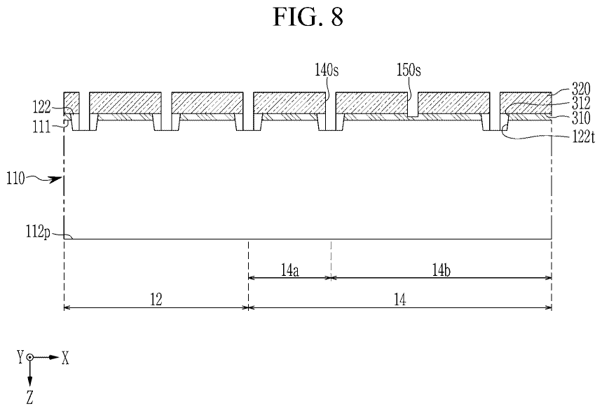

Subsequently, as illustrated in FIG. 8, a mask layer 320 may be formed, and a first preliminary trench 140s and a second preliminary trench 150s may be formed. The second preliminary trench 150s may have a depth less than a depth of the first preliminary trench 140s. The first preliminary trench 140s may be formed to correspond to the portion in which the first isolation portion 140 will be disposed, and the second preliminary trench 150s may be formed to correspond to the portion in which the second isolation portion 150 will be disposed.

For example, the mask layer 320 may be formed on the first substrate surface 111 of the substrate 110 (more particularly, on the device isolation portion 122 and the mask pattern 310 that is disposed on the first substrate surface 111). The mask layer 320 may be a type of a hard mask layer. The mask layer 320 may include any of various insulating materials. The mask layer 320 may include an insulating material that is different from a material of the mask pattern 310 and is the same as a material of the device isolation portion 122. For example, the mask layer 320 may include silicon oxide.

Accordingly, the device isolation portion 122 and the mask layer 320 include the same insulating material (e.g., silicon oxide) in the portion where the device isolation portion 122 is disposed, and the mask pattern 310 and the mask layer 320 may include different materials in the portion where the device isolation portion 122 is not disposed. For example, the mask pattern 310 may include silicon nitride.

Through an etching process, the first preliminary trench 140s may be formed in the portion where the device isolation portion 122 is disposed and the second preliminary trench 150s may be formed in the portion where the device isolation portion 122 is not disposed. In the etching process, an etching material that is capable of etching the device isolation portion 122 and the mask layer 320 and has difficulty to etch the mask pattern 310 or has a relatively low etch rate to the mask pattern 310 may be used. Thereby, in the portion where the device isolation portion 122 is disposed, the first preliminary trench 140s that extends to a lower surface of the device isolation portion 122 inside the substrate 110 and has a relatively large depth may be formed. In the portion where the device isolation portion 122 is not disposed, the second preliminary trench 150s that extends to the mask pattern 310 on the first substrate surface 111 of the substrate 110 and has a relatively small depth may be formed. By using etch selectivity of the device isolation portion 122, the mask pattern 310, and the mask layer 320, the first preliminary trench 140s and the second preliminary trench 150s that have different depths may be formed by an easy process.

However, the embodiments are not limited thereto, and the device isolation portion 122 may be disposed in the portion where the second isolation portion 150 will be formed. In this instance, the first preliminary trench 140s and the second preliminary trench 150s that have different depths may be formed by any of various methods, such as, using an additional mask or so on.

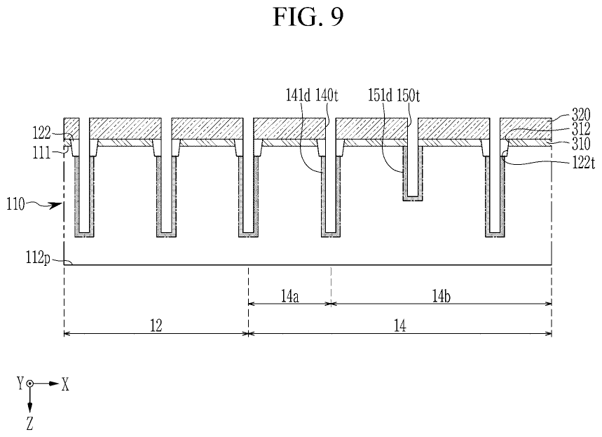

Subsequently, as illustrated in FIG. 9, a first trench 140t and a second trench 150t may be formed and first doping portions 141d and 151d may be formed.

For example, the first trench 140t and the second trench 150t may be formed by performing an etching process to pass through, extend into, or penetrate a part of the substrate 110 using the first preliminary trench 140s (refer to FIG. 8) and the second preliminary trench 150s (refer to FIG. 8). In the etching process, an etching material that is capable of etching a material included in the substrate 110 may be used. Since the second preliminary trench 150s may have the depth less than the depth of the first preliminary trench 140s, the second trench 150t that has a depth less than a depth of the first trench 140t may be formed. Thereby, the first trench 140t and second trench 150t that have different depths may be formed by an easy process.

Each of the first trench 140t and second trench 150t may pass through, extend into, or penetrate a part of the substrate 110 and may have an inner end that is spaced apart from the preliminary surface 112p of the substrate 110 and is disposed inside or extends into the substrate 110.

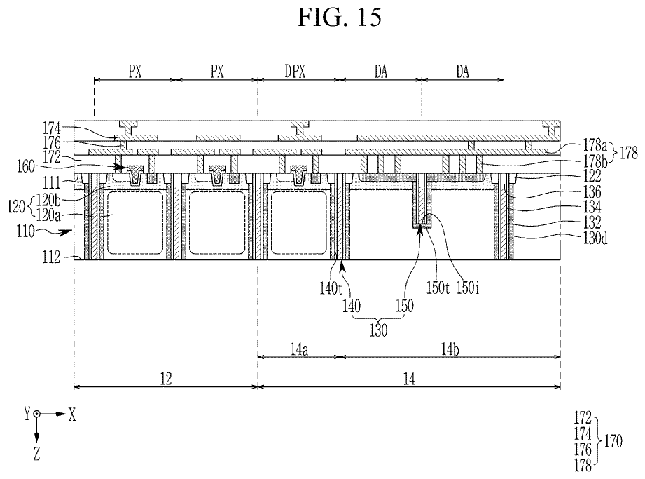

The first doping portions 141d and 151d may be formed at peripheries of the first trench 140t and second trench 150t. More particularly, a first doping portion 141d of a first doping region 140d (refer to FIG. 15) may be formed in a portion of the substrate 110 that is adjacent to a side surface and a lower surface of the first trench 140t, and a second doping portion 152d of a second doping region 150d (refer to FIG. 15) may be formed in a portion of the substrate 110 that is adjacent to a side surface and a lower surface of the second trench 150t. The first doping portion 141d of the first doping region 140d and the first doping portion 151d of the second doping region 150d may be formed by a same doping process, and thus, a process may be simplified. However, the embodiments are not limited thereto, and the first doping portion 141d of the first doping region 140d and the first doping portion 151d of the second doping region 150d may be formed by different processes.

For a doping process of forming the first doping portion 141d of the first doping region 140d and/or the first doping portion 151d of the second doping region 150d, any of various doping processes, for example, a plasma doping process may be used. The first doping portion 141d of the first doping region 140d and/or the first doping portion 151d of the second doping region 150d may have a first conductivity type.

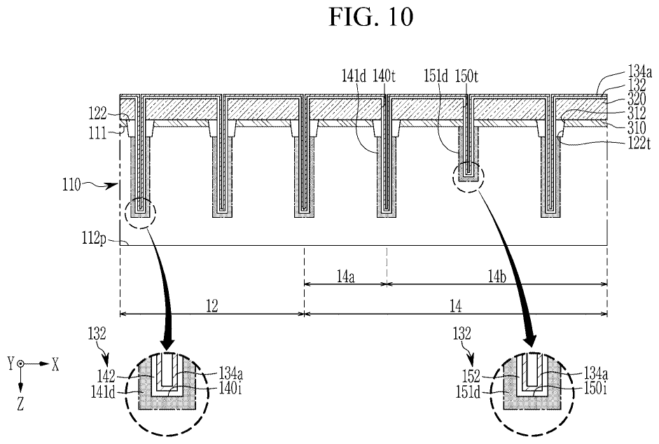

Subsequently, as illustrated in FIG. 10 to FIG. 13, an isolation portion 130 may be formed. In some embodiments, in a process forming the isolation portion 130, a portion of the sidewall insulation layer 132 that is adjacent to the lower surface of the isolation portion 130 inside the substrate 110 may be removed.

As illustrated in FIG. 10, the sidewall insulation layer 132 may be formed in each of the first trench 140t and the second trench 150t, and a first layer 134a of a conductive layer 134 may be formed.

For example, the sidewall insulation layer 132 may be formed to have a substantially uniform thickness on an inner surface of each of the first trench 140t and the second trench 150t. In this instance, the sidewall insulation layer 132 (e.g., a first sidewall insulation layer 142) that is disposed on the inner surface of the first trench 140t may be formed on an entire portion of an inner side surface and an inner end 140i of the first trench 140t, and the sidewall insulation layer 132 (e.g., a second sidewall insulation layer 152) that is disposed on the inner surface of the second trench 150t may be formed on an entire portion of an inner side surface and an inner end 150i of the second trench 150t. Further, the sidewall insulation layer 132 may be entirely disposed on the first substrate surface 111 of the substrate 110 (e.g., on the mask layer 320 that is disposed on the mask pattern 310).

The first layer 134a of the conductive layer 134 may be formed to have a uniform thickness on the sidewall insulation layer 132 on the inner surface of each of the first trench 140t and the second trench 150t. The first layer 134a of the conductive layer 134 may be entirely formed on the sidewall insulation layer 132 on the inner surface of the first trench 140t, and the first layer 134a of the conductive layer 134 may be entirely formed on the sidewall insulation layer 132 on the inner surface of the second trench 150t. Further, the first layer 134a of the conductive layer 134 may be entirely disposed on the first substrate surface 111 of the substrate 110 (e.g., on the sidewall insulation layer 132). The first layer 134a of the conductive layer 134 may include an undoped semiconductor material (e.g., a polycrystalline semiconductor material, as an example, polycrystalline silicon), but the embodiments are not limited thereto.

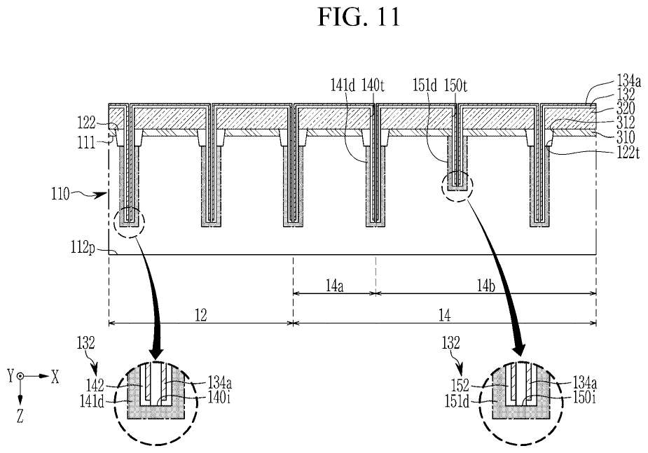

Subsequently, as illustrated in FIG. 11, a partial portion of the sidewall insulation layer 132 that is disposed on the inner end 150i of the second trench 150t inside the substrate 110 may be removed. In some embodiments, in a process of removing the partial portion of the sidewall insulation layer 132 that is disposed on the inner end 150i of the second trench 150t inside the substrate 110, a partial portion of the sidewall insulation layer 132 that is disposed on the inner end 140i of the first trench 140t inside the substrate 110 may be removed together. Further, when a partial portion of the sidewall insulation layer 132 is removed, a partial portion of the first layer 134a of the conductive layer 134 that is disposed on the partial portion of the sidewall insulation layer 132 may be removed together.

The process of removing the partial portion of the sidewall insulation layer 132 may be performed by etching the sidewall insulation layer 132 and the first layer 134a of the conductive layer 134 by a sum of a thickness of the sidewall insulation layer 132 and a thickness of the first layer 134a of the conductive layer 134 through an etching process. In the etching process, an etching material that is capable of removing the sidewall insulation layer 132 and the first layer 134a of the conductive layer 134 may be used. As such, by the etching process that is performed on an entire portion, a process may be simplified. However, the embodiments are not limited thereto. In some embodiments, a patterning process or so on that is capable of removing the partial portion of the sidewall insulation layer 132 and/or the partial portion of the first layer 134a of the conductive layer 134 may be used. In some embodiments, the partial portion of the sidewall insulation layer 132 may be removed without a process of forming the first layer 134a of the conductive layer 134.

In some embodiments, by forming the first layer 134a of the conductive layer 134 and then performing the etching process of removing the partial portion of the sidewall insulation layer 132, the first layer 134a of the conductive layer 134 may protect the sidewall insulation layer 132. However, the embodiments are not limited thereto, and a manufacturing order of the etching process of removing the partial portion of the sidewall insulation layer 132 may be variously modified.

After the etching process of removing the partial portion of the sidewall insulation layer 132, a doping process of doping the first layer 134a of the conductive layer 134 may be performed. Thereby, the first layer 134a of the conductive layer 134 may include a doped semiconductor material (e.g., a p-type polycrystalline semiconductor material, as an example, p-type polycrystalline silicon), but the embodiments are not limited thereto. In some embodiments, a manufacturing order of the doping process of doping at least a partial portion of the conductive layer 134 may be variously modified.

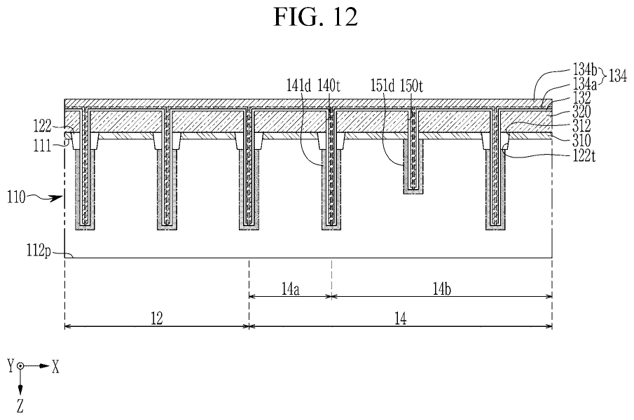

Subsequently, as illustrated in FIG. 12, a second layer 134b of the conductive layer 134 may be formed. For example, the second layer 134b of the conductive layer 134 may be formed on the first layer 134a of the conductive layer 134 on the inner surface of each of the first trench 140t and the second trench 150t. In the first trench 140t, the second layer 134b of the conductive layer 134 may fill at least a partial portion of an inner space of the first trench 140t on the first layer 134a of the conductive layer 134. In the second trench 150t, the second layer 134b of the conductive layer 134 may fill at least a partial portion of an inner space of the second trench 150t on the first layer 134a of the conductive layer 134. Further, the second layer 134b of the conductive layer 134 may be entirely disposed on the first substrate surface 111 of the substrate 110 (e.g., on the first layer 134a of the conductive layer 134 that is disposed on the first substrate surface 111).

For example, the second layer 134b of the conductive layer 134 may include an undoped semiconductor material (e.g., an intrinsic polycrystalline semiconductor material, as an example, intrinsic polycrystalline silicon), but the embodiments are not limited thereto. In some embodiments, in the process of forming the second layer 134b of the conductive layer 134 or a subsequent process, a dopant included in the first layer 134a of the conductive layer 134 may be diffused to at least a partial portion of the second layer 134b of the conductive layer 134 and thus at least the partial portion of the second layer 134b of the conductive layer 134 may include a doped semiconductor material.

Subsequently, as illustrated in FIG. 13, an isolation portion 130 may be formed by forming a capping portion 136.

For example, a partial portion of the conductive layer 134 may be etched by an etch back process. In the etch back process, an etching material that is capable of etching the conductive layer 134 may be used. The capping portion 136 may be formed inside each of the first trench 140t and the second trench 150t. A first capping portion 146 may be formed inside the first trench 140t, and a second capping portion 156 may be formed inside the second trench 150t.

The mask pattern 310 (refer to FIG. 12), the mask layer 320 (refer to FIG. 12), a portion of the sidewall insulation layer 132, and a portion of the conductive layer 134 that are disposed on the first substrate surface 111 may be removed. For example, for the removing process, a chemical mechanical polishing (CMP) process, an etching process, or so on may be used. Thereby, the isolation portion 130 may be formed.

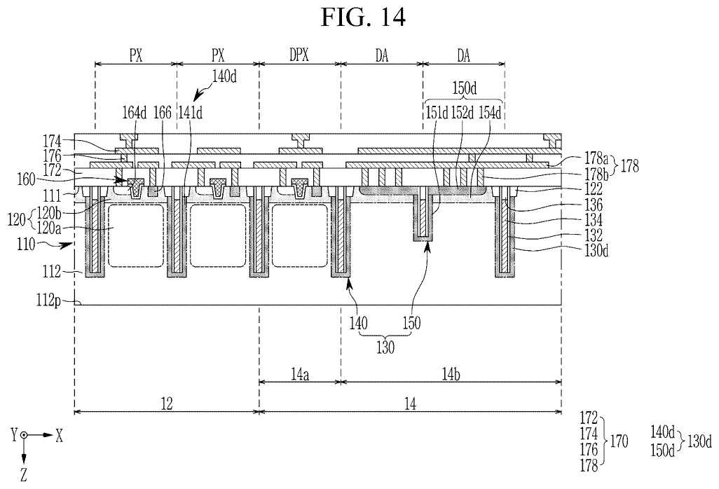

Subsequently, as illustrated in FIG. 14, in a dummy region D, a base doping portion 154d and a second doping portion 152d may be formed. In this instance, a photoelectric conversion portion 120 and a pixel circuit 160 may be formed in pixel regions PX and/or at least a part of dummy pixel regions DPX. The photoelectric conversion portion 120 may include a second conductivity type well 120a, and further include a first conductivity type well 120b. A dopant region 166, a floating diffusion region 164b, or so on may be formed as the pixel circuit 160. A wiring portion 170 that is electrically connected to the pixel circuit 160 may be formed.

For example, the second conductivity type well 120a may be formed in the pixel regions PX and/or at least the part of the dummy pixel regions DPX. The second conductivity type well 120a might not be formed in the dummy region DA.

In the pixel regions PX and/or at least the part of the dummy pixel regions DPX, the first conductivity type well 120b may be formed to be adjacent to the first substrate surface 111. In this instance, the base doping portion 154d may be formed in the dummy region DA. The first conductivity type well 120b and the base doping portion 154d may be formed together by a same doping process, or may be formed by different processes.

In the pixel regions PX and/or at least the part of the dummy pixel regions DPX, the dopant region 166, floating diffusion region 164b, or so on may be formed. In this instance, the second doping portion 152d may be formed in the dummy region DA. The dopant region 166 and the second doping portion 152d may be formed together by a same doping process, or may be formed by different processes.

In the pixel regions PX and/or at least a part of the dummy pixel regions DPX, a transistor 162, a transfer transistor 164, or so on may be formed. For a process of forming the transistor 162, the transfer transistor 164, or so on, any of various processes may be applied.

The wiring portion 170 that is electrically connected to the pixel circuit 160 may be formed. The wiring portion 170 may include a connection wiring 178 that is electrically connected to the second doping region 150d. For a process of forming the wiring portion 170, any of various processes may be applied.

Subsequently, as illustrated in FIG. 15, a partial portion of the substrate 110 including the preliminary surface 112p (refer to FIG. 14) of the substrate 110 may be removed. For example, by performing a grinding process, a polishing process, an abrasive process, an etching process, or so on to the preliminary surface 112p of the substrate 110, the partial portion of the substrate 110 may be removed up to a portion where the first isolation portion 140 is disposed. For example, the partial portion of the substrate 110 may be removed so that the first isolation portion 140 passes through or penetrates a second substrate surface 112 of the substrate 110. In this instance, the inner end 150i of the second isolation portion 150 may be spaced apart from the second substrate surface 112 of the substrate 110.

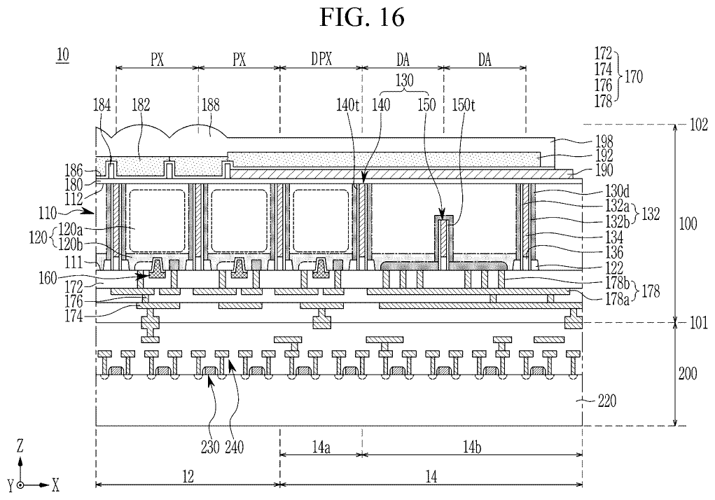

Subsequently, as illustrated in FIG. 16, an additional wiring portion 200 may be formed on the first substrate surface 111 of the substrate 110, a light receiving portion that includes a color filter 182, a micro lens 188, or so on may be formed on the second substrate surface 112 of the substrate 110, and a recess portion 212 (refer to FIG. 3) configured to expose a pad 210 (refer to FIG. 3) may be formed.

For the process of forming the additional wiring portion 200, the process of forming the light receiving portion, or the process of forming the recess portion 212, any of various processes may be applied. A manufacturing order of the process of forming the additional wiring portion 200, the process of forming the light receiving portion, or the process of forming the recess portion 212 may be variously modified.

According to some embodiments, the image sensor 10 that includes the first and second isolation portions 140 and 150 having different depths and includes the first and second doping regions 140d and 150d having different shapes may be formed by an easy process. The connection wiring 178 configured to apply a voltage to the isolation portion 130 may be disposed to be adjacent to the first substrate surface 111 of the substrate 110, and thus, the process of forming the connection wiring 178, the process of connecting the connection wiring 178 and the pad 210 may be easily performed. Thereby, productivity and yield of the image sensor 10 having enhanced performance may be enhanced.

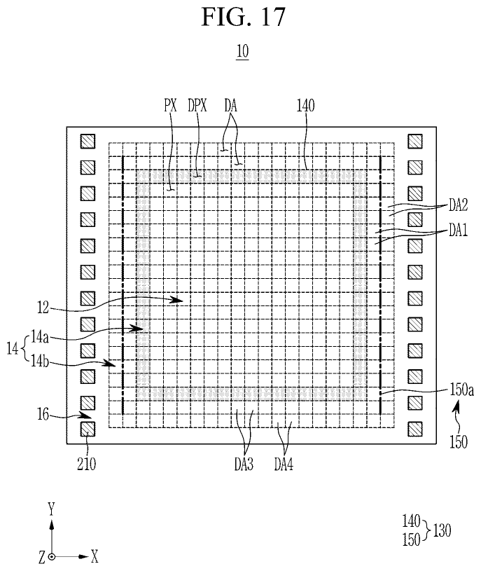

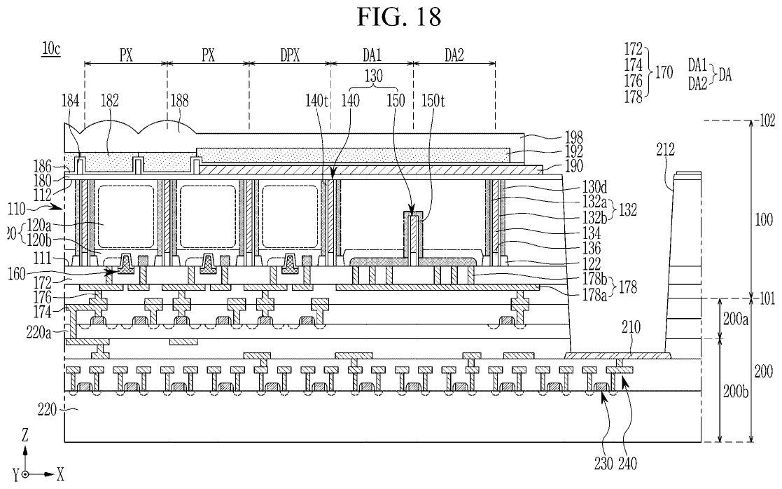

Referring to FIG. 17 and to FIG. 18, image sensors according to embodiments will be described in detail. To the extent that an element is not described in detail below, it may be understood that the element is at least substantially similar (and/or the same as) to a corresponding element that has been described elsewhere within the present disclosure. A portion which is not described in the above will be described in detail.

FIG. 17 is a plan view that schematically illustrates an image sensor 10 according to some embodiments. FIG. 17 illustrates a portion corresponding to FIG. 2.

Referring to FIG. 17, in some embodiments, a second isolation portion 150 may include a first extension portion 150a extending in a first direction (a Y-axis direction in the drawings). The second isolation portion 150 might not include a second extension portion 150b (refer to FIG. 2) extending in a second direction (an X-axis direction in the drawings) that is transverse to or crosses (e.g., perpendicular to) the first direction. However, the embodiments are not limited thereto, and a position, a shape, or so on of the second isolation portion 150 may be variously modified. In some embodiments, the second isolation portion 150 may include the second extension portion 150b, and might not include the first extension portion 150a.

Description of a first extension portion 150a and/or a second extension portion 150b with reference to FIG. 2 may be applied to the first extension portion 150a and/or the second extension portion 150b as is. Embodiments and/or modified embodiments of the first extension portion 150a and/or the second extension portion 150b described with reference to FIG. 2 may be applied to the first extension portion 150a and/or the second extension portion 150b.

FIG. 18 is a cross-sectional view that schematically illustrates an image sensor 10c according to some embodiments. FIG. 18 illustrates a portion corresponding to FIG. 3.

Referring to FIG. 18, in an image sensor 10c according to some embodiments, an additional wiring portion 200 may include a first additional wiring portion 200a and a second additional wiring portion 200b that are disposed on a first surface 101 of a photoelectric conversion substrate 100. Thereby, the image sensor 10c may have a multi-layered stacking structure that include the photoelectric conversion substrate 100, and the first and second additional wiring portions 200a and 200b.

In FIG. 18, it is illustrated as an example that a pad 210 for a connection to an outside element is disposed in the second additional wiring portion 200b, but the embodiments are not limited thereto. In some embodiments, the pad 210 for the connection to the outside may be disposed in the first additional wiring portion 200a. In this instance, the pad 210 may be disposed on the first surface 101 of the photoelectric conversion substrate 100, like a connection wiring 178 that is electrically connected to a second conductive portion of a second isolation portion 150. In some embodiments, the pad 210 for the connection to the outside may be disposed in the wiring portion 170 that is included in the photoelectric conversion substrate 100. In this instance, the pad 210 may be disposed to be adjacent to the first surface 101 of the photoelectric conversion substrate 100, like the connection wiring 178 that is electrically connected to the second conductive portion of the second isolation portion 150.

In FIG. 18, it is illustrated as an example that the wiring portion 170 and the first additional wiring portion 200a are bonded by hybrid bonding including metal bonding and insulation-layer bonding and the first additional wiring portion 200a includes a semiconductor substrate 220a, but the embodiments are not limited thereto. In some embodiments, the wiring portion 170 and the first additional wiring portion 200a are bonded by insulation-layer junction, and then, a connection member or so on configured to connect the wiring portion 170 and the first additional wiring portion 200a may be formed. The first additional wiring portion 200a and the second additional wiring portion 200b are bonded by hybrid bonding including metal bonding and insulation-layer bonding, but the embodiments are not limited thereto.

When the first and second additional wiring portions 200a and 200b may be further included as in the above, congestion of wirings, circuit elements, or so on that are included in the wiring portion 170 and the first and second additional wiring portions 200a and 200b may be effectively reduced. As a result, an area (e.g., a planar area) of the pixel region PX of the image sensor 10c may be reduced and thus an integration degree and properties of the image sensor 10c may be enhanced.

For example, the wiring portion 170 may include a wiring that is connected to the pixel circuit 160, the first additional wiring portion 200a may include a circuit element (e.g., a transistor), a wiring, or so on, and the second additional wiring portion 200b may include a logic circuit portion, a power supply portion, a wiring, or so on. However, the embodiments are not limited thereto. A wiring, a circuit element, or so on included in the wiring portion 170, and the first and second additional wiring portions 200a and 200b may be variously modified. In some embodiments, the image sensor 10c may further include an additional wiring portion other than the first and second additional wiring portions 200a and 200b.

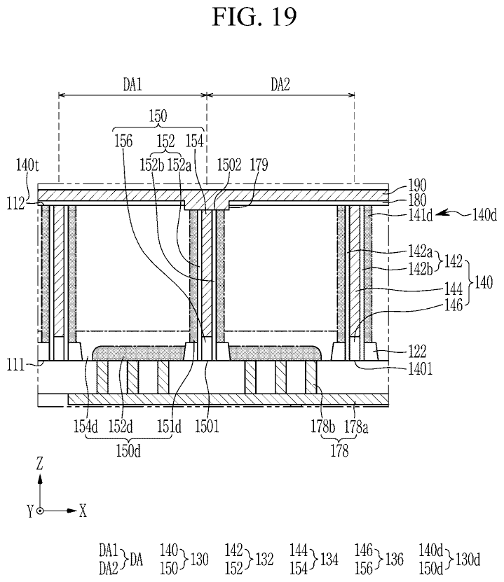

FIG. 19 is a cross-sectional view that schematically illustrates an image sensor according to some embodiments. FIG. 19 illustrates a portion corresponding to FIG. 5 and a connection contact 179.

Referring to FIG. 19, in some embodiments, a second isolation portion 150 may have a depth the same as or similar to a depth of a first isolation portion 140, and a second end 1502 of the second isolation portion 150 may be adjacent to a second substrate surface 112. That is, the second end 1502 of the second isolation portion 150, which is a conductive end to which a conductive layer 134 (e.g., a second conductive portion 154) is exposed to allow an electrical connection with another portion, may be adjacent to the second substrate surface 112. A first doping portion 151d of a second doping region 150d may be disposed on a side surface of the second isolation portion 150.

The phrase that the first isolation portion 140 and the second isolation portion 150 have the same or similar depth may refer that the first isolation portion 140 and the second isolation portion 150 are manufactured by the same manufacturing process and thus have a depth difference within a margin of error. The phrase that the first isolation portion 140 and the second isolation portion 150 have the same or similar depth may refer that the first isolation portion 140 and the second isolation portion 150 are manufactured by the same manufacturing process and then a connection contact 179 is formed at a portion where the second isolation portion 150 is disposed. In this instance, except for a portion where the connection contact 179 is disposed, the first isolation portion 140 and the second isolation portion 150 may have the substantially same depth.

In some embodiments, the first isolation portion 140 and the second isolation portion 150 may be manufactured by the same manufacturing process. For example, a device isolation portion 122 may be disposed at a portion where the first isolation portion 140 is disposed, and the device isolation portion 122 is disposed at a portion where the second isolation portion 150 is disposed. The first isolation portion 140 may pass through, extend into, or penetrate a partial portion (e.g., a central portion) of the device isolation portion 122, and the second isolation portion 150 may pass through, extend into, or penetrate a partial portion (e.g., a central portion) of the device isolation portion 122. However, the embodiments are not limited thereto.

In some embodiments, the connection contact 179 may be disposed to correspond to a portion where the second isolation portion 150 is disposed at a side of the second substrate surface 112. In some embodiments, the connection contact 179 may be connected to an optical black layer 190. For example, the connection contact 17 may be formed of a partial portion of the optical black layer 190. Thereby, the optical black layer 190 that includes the connection contact 179 may be easily formed by forming an opening for the connection contact 179 at a horizontal insulation layer 180 and then forming the optical black layer 190. However, the embodiments are not limited thereto. In some embodiments, the connection contact 179 may be separately formed from the optical black layer 190, or the optical black layer 190 may be omitted.

The optical black layer 190 and/or the connection contact 179 may include a metal material, and may include a single layer or a plurality of layers. For example, the optical black layer 190 and/or the connection contact 179 may include a metal layer that includes at least one of tungsten, aluminum, copper, titanium, or tantalum, or an alloy including the same. The optical black layer 190 and/or the connection contact 179 may further include a diffusion barrier layer between the horizontal insulation layer 180 and the metal layer. The diffusion barrier layer may include a metal nitride layer that includes titanium nitride, tantalum nitride, tungsten nitride, or so on. However, the embodiments are not limited thereto, and the optical black layer 190 and/or the connection contact 179 may include any of various materials or have any of various stacking structures.

The first doping portion 151d of the second doping region 150d that is disposed at the side surface of the second isolation portion 150 may be electrically connected to the conductive layer 134 (e.g., the second conductive portion 154) of the second isolation portion 150 through the connection contact 179 that is adjacent to the second substrate surface 112.

In FIG. 19, it is illustrated as an example that the second end 1502 of the second isolation portion 150 is disposed inside or extends into the substrate than the second substrate surface 112, but the embodiments are not limited thereto. The second end 1502 of the second isolation portion 150 may include a portion that is on the same plane as the second substrate surface 112.

According to some embodiments, the first isolation portion 140 and the second isolation portion 150 may be manufactured by the same manufacturing process and a doping region 130d that is connected to a connection wiring 178 is connected to the conductive layer 134 of an isolation portion 130 through the connection contact 179. The connection wiring 178 may be included in a wiring portion that is disposed to be adjacent to the first substrate surface 111 of the substrate 110 and thus a path for applying a voltage to the isolation portion 130 may be reduced. Further, the first isolation portion 140 and the second isolation portion 150 may be manufactured by the same manufacturing process and thus a process may be simplified.

While some examples have been described in connection with what is presently considered to be some practical embodiments, it is to be understood that the disclosure is not limited to the disclosed embodiments, and that the disclosure is intended to cover various modifications and equivalent arrangements included within the spirit and scope of the appended claims.

What is claimed is:

1. An image sensor, comprising:
a substrate;
a plurality of unit regions, wherein at least one of the plurality of unit regions include a photoelectric conversion portion in the substrate;
a plurality of isolation portions that are disposed to correspond to a boundary of the plurality of unit regions; and
a doping region in the substrate,
wherein the plurality of isolation portions include a first isolation portion and a second isolation portion that has a height less than a height of the first isolation portion,
wherein the plurality of isolation portions include a conductive layer, and
wherein the doping region is electrically connected to a portion of the conductive layer in the second isolation portion.

2. The image sensor of claim 1, wherein the substrate has a first substrate surface and a second substrate surface opposite to each other, and
wherein the second isolation portion extends into the substrate, a first end of the second isolation portion is adjacent to the first substrate surface, and a second end of the second isolation portion is spaced apart from the second substrate surface of the substrate.

3. The image sensor of claim 2, wherein the second end of the second isolation portion comprises a conductive end through which the conductive layer is exposed, and
wherein the doping region is electrically connected to the conductive end of the second isolation portion.

4. The image sensor of claim 1, wherein the doping region includes a first doping region that is on the first isolation portion and a second doping region that is on the second isolation portion, and
wherein the first doping region and the second doping region have different shapes.

5. The image sensor of claim 4, wherein the second isolation portion includes a conductive end that extends into the substrate and through which the conductive layer is exposed to the second doping region,
wherein the first doping region includes a first doping portion that is on a side surface of the first isolation portion, and
wherein the second doping region includes a first doping portion that is on a side surface of the second isolation portion and on the conductive end and is electrically connected to the conductive end, and includes a second doping portion that is adjacent to a first substrate surface of the substrate and is connected to the first doping portion.

6. The image sensor of claim 1, wherein the substrate has a first substrate surface and a second substrate surface opposite to each other,
wherein the first isolation portion extends into the substrate, and
wherein a first end of the first isolation portion is adjacent to the first substrate surface, and a second end of the first isolation portion is adjacent to the second substrate surface.

7. The image sensor of claim 1, wherein a portion of the conductive layer in the first isolation portion is electrically connected to the doping region through the portion of the conductive layer in the second isolation portion.

8. The image sensor of claim 1, further comprising:
a device isolation portion that has a height that is less than a height of one of the plurality of isolation portions,
wherein the device isolation portion is adjacent to the first isolation portion, and is spaced apart from the second isolation portion.

9. The image sensor of claim 1, wherein the substrate includes a pixel array region and a dummy array region,
wherein the plurality of unit regions include a plurality of pixel regions in the pixel array region and a plurality of dummy regions in the dummy array region, and
wherein the second isolation portion is at least at a boundary of ones of the plurality of dummy regions.

10. The image sensor of claim 9, wherein, in a plan view, the second isolation portion includes at least one of a first extension portion or a second extension portion,
wherein the first extension portion extends in a first direction between the ones of the plurality of dummy regions, and
wherein the second extension portion extends in a second direction that intersects the first direction and the second extension portion is between ones of the plurality of dummy regions.

11. The image sensor of claim 1, further comprising:
a connection wiring that is on a first substrate surface of the substrate and is electrically connected to the doping region; and
a light receiving portion that is on a second substrate surface of the substrate that is opposite to the first substrate surface of the substrate.

12. The image sensor of claim 11, wherein the doping region includes a doping portion that is adjacent to the first substrate surface, and
wherein the connection wiring includes a connection contact via that is directly connected to the doping portion.

13. The image sensor of claim 11, further comprising:
a wiring portion that is adjacent to the first substrate surface; and
a pad that is electrically connected to the wiring portion at a side of the first substrate surface and is configured to be electrically connected to an outside element,
wherein the connection wiring is included in the wiring portion.

14. The image sensor of claim 11, comprising:
a photoelectric conversion substrate that includes the substrate, the photoelectric conversion portion, the plurality of isolation portions, the doping region, the connection wiring, and the light receiving portion; and
an additional wiring portion that is on a first surface of the photoelectric conversion substrate at a side of the first substrate surface of the substrate and includes a pad that is electrically connected to the connection wiring and is configured to be electrically connected to an outside element.

15. An image sensor, comprising:
a substrate;
a pixel array region comprising a plurality of pixel regions and a dummy array region comprising a plurality of dummy regions, wherein the plurality of pixel regions include a plurality of photoelectric conversion portions, respectively, in the substrate;
a first isolation portion in the pixel array region between ones of the plurality of photoelectric conversion portions of the plurality of pixel regions;
a second isolation portion that extends into the substrate to correspond to at least at a boundary of ones of the plurality of dummy regions and includes a conductive end through which a conductive layer is exposed; and
a doping region that is in the substrate and is electrically connected to the conductive end of the second isolation portion.

16. The image sensor of claim 15, further comprising:
a wiring portion that is adjacent to a first substrate surface of the substrate,
wherein the doping region includes a second doping region that is on the second isolation portion, and
wherein the second doping region includes a first doping portion that is on a side surface of the second isolation portion and the conductive end and is electrically connected to the conductive end, and a second doping portion that is adjacent to the first substrate surface of the substrate and is connected to the first doping portion.

17. The image sensor of claim 16, wherein the first doping portion is directly connected to the conductive end; or
wherein the first doping portion is electrically connected to the conductive end through a connection contact on a second substrate surface of the substrate that is opposite to the first substrate surface.

18. The image sensor of claim 15, further comprising:
a connection wiring that is on a first substrate surface of the substrate and is electrically connected to the doping region; and
a light receiving portion that is on a second substrate surface of the substrate that is opposite to the first substrate surface of the substrate.

19. An image sensor, comprising:
a photoelectric conversion substrate; and
an additional wiring portion that is on a first surface of the photoelectric conversion substrate and includes a pad configured to be electrically connected to an outside element,
wherein the photoelectric conversion substrate includes:
a substrate;
a plurality of unit regions, wherein at least one of the plurality of unit regions include a photoelectric conversion portion in the substrate;
a plurality of isolation portions that are disposed to correspond to a boundary of the plurality of unit regions, wherein the plurality of isolation portions include a conductive layer;
a doping region that is in the substrate and is electrically connected to a portion of the conductive layer of the plurality of isolation portions; and
a wiring portion that is adjacent to a first substrate surface of the substrate, and is electrically connected to the additional wiring portion, and
wherein the wiring portion includes a connection wiring that is electrically connected to the doping region.

20. The image sensor of claim 19, wherein the conductive layer of the plurality of isolation portions is configured to receive a negative voltage through the connection wiring and the doping region.
